(19) United States
(12) Patent Application Publication
(10) Pub. No.: US 2026/0033310 A1
(43) Pub. Date: Jan. 29, 2026

(54) MICROELECTRONIC DEVICES WITH THROUGH-STACK VIAS WITHIN SHALLOW STADIUMS AND OUTSIDE OF DEEP STADIUMS, AND RELATED METHODS

(71) Applicant: Micron Technology, Inc., Boise, ID (US)

(72) Inventors: Lifang Xu, Boise, ID (US); Umberto Maria Meotto, Dietlikon (CH); Domenico Tuzi, Balsorano (IT); David H. Wells, Boise, ID (US); Richard J. Hill, Boise, ID (US); Indra V. Chary, Boise, ID (US)

(21) Appl. No.: 19/251,332

(22) Filed: Jun. 26, 2025

Related U.S. Application Data
(60) Provisional application No. 63/676,285, filed on Jul. 26, 2024.

(51) Int. Cl. H01L 23/48; H01L 21/768; H10B 41/10; H10B 41/27; H10B 43/10; H10B 43/27

(52) U.S. Cl. CPC H01L 23/481; H01L 21/76877; H10B 41/27; H10B 43/27; H10B 41/10; H10B 43/10

(57) ABSTRACT

A microelectronic device includes a stack with vertically repeated tiers respectively including insulative and conductive structure(s). Slits divide the stack into blocks. Within a block, a series of stadiums is formed with stadiums horizontally spaced by crests. The stadiums are individually defined in unique groups of the tiers and include staircase(s). A first stadium of the series is defined in a first tier group elevationally above a second tier group in which a second stadium is defined. Step contacts extend to or into steps of the staircase(s). Through-stack vias extend a height of the stack and are in electrical communication with the step contacts. Some through-stack vias are within the first stadium area and are in electrical communication with the first stadium's step contacts. Other through-stack vias are within the crests and are in electrical communication with the second stadium's step contacts. Related methods and systems are also disclosed.

### CROSS-REFERENCE TO RELATED APPLICATION

This application claims the benefit under 35 U.S.C. § 119 (e), of U.S. Provisional Patent Application Ser. No. 63/676,285, filed Jul. 26, 2024, the disclosure of which is hereby incorporated in its entirety herein by this reference.

### TECHNICAL FIELD

Embodiments of the disclosure relate to the field of microelectronic device design and fabrication. More particularly, the disclosure relates to microelectronic devices (e.g., memory devices, such as 3D NAND memory devices) and with series of staircased stadiums formed in a stack having a vertically repeated pattern of tiers of conductive and insulative structures. The disclosure also relates to methods for forming such devices and to systems incorporating such devices.

### BACKGROUND

Memory devices provide data storage for electronic systems. A Flash memory device is one of various memory device types and has numerous uses in modern computers and other electrical devices. A conventional Flash memory device may include a memory array that has a large number of charge storage devices (e.g., memory cells, such as non-volatile memory cells) arranged in rows and columns. In a NAND architecture type of Flash memory, memory cells arranged in a column are coupled in series, and a first memory cell of the column is coupled to a data line (e.g., a bit line). In a “three-dimensional NAND” memory device (which may also be referred to herein as a “3D NAND” memory device), a type of vertical memory device, not only are the memory cells arranged in row and column fashion in a horizontal array, but tiers of the horizontal arrays are stacked over one another (e.g., as vertical strings of memory cells) to provide a “three-dimensional array” of the memory cells. The stack of tiers vertically alternate electrically conductive materials with electrically insulating (e.g., dielectric) materials. The conductive materials function as control gates for, e.g., access lines (e.g., word lines) of the memory cells. Vertical structures (e.g., pillars comprising channel structures and tunneling structures) extend along the vertical string of memory cells. A drain end of a string may be adjacent a top and/or bottom of the vertical structure (e.g., pillar), and a source end of the string may be adjacent some other portion of the pillar, such as the other of the top and bottom of the pillar or a middle portion of the pillar. The drain end is operably connected to a bit line, while the source end is operably connected to a source structure (e.g., a source plate, a source line). A 3D NAND memory device also includes electrical connections between, e.g., access lines (e.g., word lines) and other conductive structures of the device so that the memory cells of the vertical strings can be selected for writing, reading, and erasing operations.

Some 3D NAND memory devices include so-called “staircase” structures having “steps” (or otherwise known as “stairs”) at edges (e.g., ends) of the tiers of the stack. The steps provide contact regions of conductive structures of the device (e.g., contact regions to conductive materials of the tiered stack), such as of access lines (e.g., word lines). Contact structures (e.g., so-called “step contacts”) may be formed in physical contact with the steps to provide electrical access to the conductive structures (e.g., word lines) associated with the steps. The contact structures may be in electrical communication, via conductive routing lines, to additional contact structures (so-called “through-stack vias”) that communicate through the tiered stack to additional routing lines, which may be in a source/drain region. The additional routing lines may electrically communicate to string drivers that drive the access line (e.g., word line) voltages to write to or read from the memory cells controlled via the access lines (e.g., word lines).

A continued goal in the microelectronic device fabrication industry is to design the features of the microelectronic devices so that the features may be reliably and consistently formed. However, as the horizontal footprint of device and feature sizes are reduced (e.g., scaled to smaller sizes) and as some device features are constructed at greater heights (e.g., greater height-to-width ratios), precise and accurate fabrication continues to present challenges.

### BRIEF DESCRIPTION OF THE DRAWINGS

FIG. 1 is a schematic, cross-sectional, elevational view of a microelectronic device structure of a microelectronic device, according to embodiments of the disclosure.

FIG. 2 is an enlarged view of the area of box A of FIG. 1.

FIG. 3 is a top plan, schematic view of the microelectronic device that may include the microelectronic device structure of FIG. 1, wherein the front of FIG. 1 corresponds to a view from section line C-C of FIG. 3 and other figures that include section line C-C.

FIG. 4 is a schematic, cross-sectional, perspective, enlarged view of the area of box B of FIG. 1, without through-stack vias illustrated and without fill material illustrated for case of viewing step contacts, wherein the front of FIG. 4 corresponds to a view of section line D-D of FIG. 3 and other figures that include section line D-D.

FIG. 5 is a schematic, cross-sectional, perspective, enlarged view of the area of box B of FIG. 1, with through-stack vias illustrated and without fill material illustrated for case of viewing the through-stack vias, wherein the front of FIG. 5 corresponds to a view of section line D-D of FIG. 3 and other figures that include section line D-D.

FIG. 6 is a top plan, schematic view of a microelectronic device structure that includes the microelectronic device structures of FIG. 1 and FIG. 3 and further includes upper routing between the step contacts and the through-stack vias, wherein all active through-stack vias for deep, single-set stadiums are disposed in crests of the structure, according to embodiments of the disclosure.

FIG. 7 is a top plan, schematic view of a microelectronic device structure that includes a microelectronic device structures with many of the same features as the microelectronic device structures of FIG. 1 and FIG. 3, but wherein the through-stack vias are differently arranged, such as including some active through-stack vias in a landing area of deep, single-set stadium(s) and also non-active support contacts proximate sides of the crests; and wherein routing is included between the step contacts and the active through-stack vias, according to embodiments of the disclosure.

FIG. 8 is a schematic, cross-sectional, elevational view of a pair of shallow, multi-set stadiums of a pair of neighboring, mirrored blocks of the microelectronic device structure of any of FIG. 1, FIG. 3, FIG. 6, and FIG. 7, wherein the view of FIG. 8 corresponds to a view from section line E-E of FIG. 6 and/or FIG. 7, but without full upper routing illustrated.

FIGS. 9 through 13 are schematic, cross-sectional, perspective views of various stages of processing to fabricate a microelectronic device, such as a device that includes the microelectronic device structure(s) of one or all of FIGS. 1 through 8, according to embodiments of the disclosure, wherein the views of FIGS. 9 through 13 correspond to box B of FIG. 1, correspond to the view of FIG. 4 and FIG. 5, and correspond to a view along section line D-D of FIG. 3 and FIG. 6, and wherein the sequential order of the drawings may correspond to the sequential order of the represented stages, though the disclosure is not necessarily limited to this order of fabrication stages.

FIG. 14 is a block diagram of an electronic system including a microelectronic device that includes at least one microelectronic device structure of embodiments of the disclosure.

### DETAILED DESCRIPTION

Structures (e.g., microelectronic device structures), apparatuses (e.g., microelectronic devices), and systems (e.g., electronic systems), according to embodiments of the disclosure, include a stack having a vertically repeated pattern of tiers of conductive and insulative structures. Slit structures extend vertically through the stack to divide the stack into blocks. Within respective individual blocks, a series of stadiums is patterned into the tiered stack of the block. Non-patterned “crest” portions of the stack space laterally neighboring stadiums, of the block, from one another, and at least one additional non-patterned “bridge” portion of the stack extends along a width of the block so that conductive structures of the stack provide a continuous conductive region across the width of the block. The stadiums include staircase structures having steps at ends of stepped tiers of the stack. The steps include treads defined by exposed upper horizontal surfaces of structures (e.g., insulative structures) of the stepped tiers. At least one conductive “step contact” (e.g., access line contact, word line contact) extends to and/or into a respective step of the staircases. Through-stack vias extend through portions of the stack to and/or into a base region below the stack. At least some of the through-stack vias are in electrical communication with the step contacts and also with string drivers. These “active” through-stack vias enable electrical communication between the string drivers, the step contacts, and the stack's conductive structures that are included in the steps to which the step contacts connect. For relatively shallower stadiums of the block, the through-stack vias are disposed within the horizontal area of the stadiums. For relatively deeper stadiums of the block, the through-stack vias are disposed primarily within the horizontal area of the crests. In some embodiments, additional active through-stack vias of the deeper stadiums are also within the horizontal area of landing areas of the deeper stadiums. By positioning the through-stack vias, for the relatively deeper stadiums, in the crests, the through-stack vias may be more reliably and consistently formed, with less risk of structural deformations, misalignments with landing areas, and other deficiencies.

As used herein, the term “through-stack via” means and refers to a structure including electrically conductive material(s) and configured to provide electrical communication between two or more other electrically-conductive and/or electrically-operable features of a structure. The “through-stack via” extends at least partially (e.g., at least in a majority of its vertical height, e.g., substantially its whole vertical height) through elevations of the stack structure. One or more “through-stack vias” may extend substantially a whole of its height through unpatterned areas of the stack structure, and such a “through-stack via” (e.g., an insulative liner of the “through-stack via”) may be in direct physical contact with tiers of the stack structure along substantially the whole of the through-stack via's height. One or more other “through-stack vias” may extend substantially through a patterned area of the stack structure, such that a portion of the height of the “through-stack via” extends directly through some tiers of the stack structure while another portion of the height of the “through-stack via” extends directly through one or more other structures/materials, which other structures/materials may be above, below, or within the elevations of the stack structure.

As used herein, the term “series of stadiums” means and refers to a group of stadiums distributed across a stack structure in a row (e.g., in the illustrated X-axis direction), with neighboring stadiums spaced from one another by a non-patterned “crest” portion of the stack. Each block may include a single “series of stadiums.” The “series of stadiums” may share at least one common “bridge” provided by a non-patterned portion of the stack. The “bridge” may be along a front or a rear of the “series of stadiums.”

As used herein, the term “set of staircases” means and refers to one or more staircases that collectively define a row (e.g., in the illustrated X-axis direction) of steps, each of which steps may be at a respectively different tier elevation of a stack structure. A respective “set of staircases” may include one or more descending staircases, one or more ascending staircases, or any combination thereof.

As used herein, the term “descending staircase” means and refers to a staircase generally exhibiting negative slope, as defined by a phantom line extending from a vertically highest step of the staircase to a vertically lowest step of the staircase.

As used herein, the term “ascending staircase” means and refers to a staircase generally exhibiting positive slope, as defined by a phantom line extending from a vertically highest step of the staircase to a vertically lowest step of the staircase.

As used herein, the term “high-aspect-ratio” means and refers to a height-to-width (e.g., a ratio of a maximum height to a maximum width) of greater than about 10:1 (e.g., greater than about 20:1, greater than 30:1, greater than about 40:1, greater than about 50:1, greater than about 60:1, greater than about 70:1, greater than about 80:1, greater than about 90:1, greater than about 100:1).

As used herein, a feature referred to with the adjective “source/drain” means and refers to the feature being configured for association with either or both the source region and the drain region of the device that includes the “source/drain” feature. A “source region” may be otherwise configured as a “drain region” and vice versa without departing from the scope of the disclosure.

As used herein, the terms “opening,” “trench,” and “slit” mean and include a volume extending through or into at least one structure or at least one material, leaving a gap in that at least one structure or at least one material, or a volume extending between structures or materials, leaving a gap between the structures or materials. Unless otherwise described, an “opening,” “trench,” and/or “slit” is not necessarily empty of material. That is, an “opening,” “trench,” or “slit” is not necessarily void space. An “opening,” “trench,” or “slit” formed in or between structures or materials may comprise structure(s) or material(s) other than that in or between which the opening is formed. And, structure(s) or material(s) “exposed” within an opening, trench, or slit is/are not necessarily in contact with an atmosphere or non-solid environment. Structure(s) or material(s) “exposed” within an opening, trench, or slit may be adjacent or in contact with other structure(s) or material(s) that is/are disposed within the opening, trench, or slit.

As used herein, the terms “substrate,” “base structure,” and “base region” mean and include a base material, structure, region, or other construction upon which components, such as tiered stacks and structures therein, are formed. The substrate, base structure, or base region may be or include a semiconductor substrate, a base semiconductor material on a supporting structure, a metal electrode, or a semiconductor substrate having one or more materials, structures, or regions formed thereon. The substrate, base structure, or base region may be or include a “semiconductor,” “semiconductive,” and/or “semiconducting” material, such as one or more of a conventional silicon substrate or other bulk substrate including a semiconductive material. As used herein, the term “bulk substrate” means and includes not only silicon wafers, but also silicon-on-insulator (“SOI”) substrates, such as silicon-on-sapphire (“SOS”) substrates or silicon-on-glass (“SOG”) substrates, epitaxial layers of silicon on a base semiconductor foundation, or other “semiconductor,” “semiconductive,” “semiconducting,” and/or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. Furthermore, when reference is made to a “substrate,” “base structure,” or “base region” in the following description, previous process stages may have been utilized to form materials, structures, or junctions in the substrate, base structure, base region, or other foundation.

As used herein, the terms “insulative” and “insulating,” when used in reference to a material, region, or structure, means and includes a material, region, or structure that is electrically insulative or electrically insulating. An “insulative” or “insulating” material, region, or structure may be formed of and include one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric carboxynitride material (e.g., a silicon carboxynitride (SiOₓC_{z}N_{y})), and/or air. In addition, an “insulative” or “insulating” structure means and includes a structure formed of and including “insulative” or “insulating” material. In some embodiments, an “insulative” or “insulating” structure, region, or material is free or substantially free of “conductive,” “conducting,” “semiconductor,” “semiconductive,” and/or “semiconducting” material(s).

As used herein, the terms “conductive” and “conducting,” when used in reference to a material, region, or structure, mean and include a material, region, or structure that is electrically conductive or electrically conducting, unless otherwise specified (e.g., as “thermally conductive” or “thermally conducting”). A “conductive” or “conducting” material, region, or structure may be formed of and include one or more metals or metal-containing compositions. The one or more metals or metal-containing compositions may be in the form of a single homogeneous material region, in the form of multiple material regions (e.g., as one material region at least partially lined by a second material region (e.g., liner)). The metals may include one or more of tungsten (W), titanium, (Ti) nickel (Ni), platinum (Pt), rhodium (Rh), ruthenium (Ru), iridium (Ir), aluminum (Al), copper (Cu), molybdenum (Mo), silver (Ag), gold (Au). Metal-containing compositions may include one or more alloys, nitrides, silicides, carbides, and/or oxides of and include any of the foregoing metals, such as a material including one or more of titanium nitride (TiN), tantalum nitride (TaN), tungsten nitride (WN), titanium aluminum nitride (TiAlN), iridium oxide (IrOₓ), ruthenium oxide (RuOₓ), and/or alloys thereof. In some embodiments, a “conductive” or “conducting” material, region, or structure may be formed of and include one or more conductively-doped semiconductor material (e.g., conductively-doped silicon, conductively-doped germanium, conductively-doped silicon germanium) and/or polysilicon. In some embodiments, a “conductive” or “conducting” material, region, or structure is free or substantially free of “insulative,” “insulating,” “semiconductor,” “semiconductive,” and/or “semiconducting” material(s).

As used herein, the terms “semiconductor” and “semiconductive,” when used in reference to a material, region, or structure, mean and include a material, region, or structure having an electrical conductivity between those of insulative materials and conductive materials. For example, a semiconductor material may have an electrical conductivity of between about 10⁻⁸ Siemens per centimeter (S/cm) and about 10⁴ S/cm (106 S/m) at room temperature. Examples of semiconductor materials include elements found in column IV of the periodic table of elements, such as silicon (Si), germanium (Ge), and carbon (C). Other examples of semiconductor materials include compound semiconductor materials, such as binary compound semiconductor materials (e.g., gallium arsenide (GaAs)), ternary compound semiconductor materials (e.g., AlₓGa₁₋ₓAs), and quaternary compound semiconductor materials (e.g., GaₓIn₁₋ₓAs_{y}P_{1-y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials, such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and/or “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and/or “z” atoms of an additional element (if any), respectively, for every one atom of another element (e.g., Si, Al, Hf, Nb, Ti). As the formulae are representative of relative atomic ratios and not strict chemical structure, an insulative material or insulative structure may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “sacrificial,” when used in reference to a material, region, or structure, means and includes a material, region, or structure that is formed during a fabrication process but which is removed (e.g., substantially removed) prior to completion of the fabrication process.

As used herein, the term “precursor,” when referring to a material, region, or structure, means and refers to a material, region, or structure to be transformed into a resulting material, region, or structure. For example, and without limitation, a “precursor stack” may refer to a stack structure that is to be altered in its composition during formation of a final stack.

As used herein, the term “horizontal” means and includes a direction that is parallel to a primary surface of the substrate on which the referenced material, region, or structure is located. The “width” and “length” of a respective material, region, or structure may be defined as dimensions in a horizontal plane. With reference to the figures, the “horizontal” direction may be perpendicular to an indicated “Z” axis, may be parallel to an indicated “X” axis, and may be parallel to an indicated “Y” axis.

As used herein, the term “lateral” means and includes a direction in a horizontal plane parallel to a primary surface of the substrate on which a referenced material, region, or structure is located and substantially perpendicular to a “longitudinal” direction. The “width” of a respective material, region, or structure may be defined as a dimension in the lateral direction of the horizontal plane. With reference to the figures, the “lateral” direction may be parallel to an indicated “X” axis, may be perpendicular to an indicated “Y” axis, and may be perpendicular to an indicated “Z” axis.

As used herein, the term “longitudinal” means and includes a direction in a horizontal plane parallel to a primary surface of the substrate on which a referenced material, region, or structure is located, and substantially perpendicular to a “lateral” direction. The “length” of a respective material, region, or structure may be defined as a dimension in the longitudinal direction of the horizontal plane. With reference to the figures, the “longitudinal” direction may be parallel to an indicated “Y” axis, may be perpendicular to an indicated “X” axis, and may be perpendicular to an indicated “Z” axis.

As used herein, the term “vertical” means and includes a direction that is perpendicular to a primary surface of the substrate on which a referenced material, region, or structure is located. The “height” of a respective material, region, or structure may be defined as a dimension in a vertical plane. With reference to the figures, the “vertical” direction may be parallel to an indicated “Z” axis, may be perpendicular to an indicated “X” axis, and may be perpendicular to an indicated “Y” axis.

As used herein, the term “width” means and includes a dimension, along an indicated “X” axis in a horizontal plane (e.g., at a certain elevation, if identified), defining a maximum distance, along such “X” axis in the horizontal plane, of the whole of the material, region, or structure in question or of a concerned portion of the material, region, or structure in question. For example, a width of a conductive or insulative structure may be a maximum X-axis dimension from one lateral end of the conductive or insulative structure to an opposite lateral end of the structure, whereas a width of a step defined by the conductive or insulative structure may be a maximum X-axis dimension of only that portion of the conductive or insulative structure that is within the horizontal area of the step (e.g., the step tread).

As used herein, the term “length” means and includes a dimension, along an indicated “Y” axis in a horizontal plane (e.g., at a certain elevation, if identified), defining a maximum distance, along such “Y” axis in the horizontal plane, of the material, region, or structure in question or of a concerned portion of the material, region, or structure in question. For example, a length of a conductive or insulative structure may be a maximum Y-axis dimension from one block-defining slit to another block-defining slit, whereas a length of a step defined by the conductive or insulative structure may be a maximum Y-axis dimension of only that portion of the conductive or insulative structure that is within the horizontal area of the step (e.g., the step tread).

As used herein, the terms “thickness” or “thinness” are spatially relative terms that mean and include a dimension in a straight-line direction that is normal to the closest surface of an immediately adjacent material, region, or structure that is of a different composition or that is otherwise distinguishable from the material, region, or structure whose thickness, thinness, or height is discussed.

As used herein, the term “between” is a spatially relative term used to describe the relative disposition of one material, region, or structure relative to at least two other materials or structures. The term “between” may encompass both a disposition of one material, region, or structure directly adjacent the other materials or structures and a disposition of one material, region, or structure indirectly adjacent to the other materials or structures.

As used herein, the term “proximate” is a spatially relative term used to describe disposition of one material, region, or structure near to another material, region, or structure. The term “proximate” includes dispositions of indirectly adjacent to, directly adjacent to, and internal to.

As used herein, features (e.g., regions, materials, openings, structures, assemblies, devices) described as “neighboring” one another mean and include features of the disclosed identity (or identities) that are located most proximate (e.g., closest to) one another. One or more additional features (e.g., additional regions, additional materials, additional structures, additional openings, additional assemblies, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with the “neighboring” features is positioned between the “neighboring” features. For example, a structure of material X “neighboring” a structure of material Y is the first material X structure, e.g., of multiple material X structures, that is nearest the particular structure of material Y. Accordingly, features described as “vertically neighboring” one another mean and include features of the disclosed identity (or identities) that are located most vertically proximate (e.g., vertically closest to) one another. Moreover, features described as “horizontally neighboring” one another mean and include features of the disclosed identity (or identities) that are located most horizontally proximate (e.g., horizontally closest to) one another.

As used herein, the term “consistent”—when referring to a parameter, property, or condition of one structure, material, feature, or portion thereof in comparison to the parameter, property, or condition of another such structure, material, feature, or portion of such same aforementioned structure, material, or feature—is a relative term that means and includes the parameter, property, or condition of the two such structures, materials, features, or portions being equal, substantially equal, or about equal, at least in terms of respective dispositions of such structures, materials, features, or portions. For example, two structures having “consistent” heights as one another may each define a same, substantially same, or about the same height, from a lower surface to an upper surface of each respective such structure, despite the two structures being at different elevations of a larger structure.

As used herein, the terms “about” and “approximately,” when either is used in reference to a numerical value for a particular parameter, are inclusive of the numerical value and a degree of variance from the numerical value that one of ordinary skill in the art would understand is within acceptable tolerances for the particular parameter. For example, “about” or “approximately,” in reference to a numerical value, may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “substantially,” when referring to a parameter, property, or condition, means and includes the parameter, property, or condition being equal to or within a degree of variance from a given value such that one of ordinary skill in the art would understand such given value to be acceptably met, such as within acceptable manufacturing tolerances. By way of example, depending on the particular parameter, property, or condition that is substantially met, the parameter, property, or condition may be “substantially” a given value when the value is at least 90.0 percent met, at least 95.0 percent met, at least 99.0 percent met, or even at least 99.9 percent met.

As used herein, the terms “on” or “over,” when referring to an element as being “on” or “over” another element, are spatially relative terms that mean and include the element being directly on top of, adjacent to (e.g., laterally adjacent to, horizontally adjacent to, longitudinally adjacent to, vertically adjacent to), underneath, or in direct contact with the other element. It also includes the element being indirectly on top of, adjacent to (e.g., laterally adjacent to, horizontally adjacent to, longitudinally adjacent to, vertically adjacent to), underneath, or near the other element, with other elements present therebetween. In contrast, when an element is referred to as being “directly on” or “directly adjacent to” another element, there are no intervening elements present.

As used herein, other spatially relative terms, such as “below,” “lower,” “bottom,” “above,” “upper,” “top,” and the like, may be used for ease of description to describe one element's or feature's relationship to another element(s) or feature(s) as illustrated in the figures. Unless otherwise specified, any spatially relative terms used in this disclosure are intended to encompass different orientations of the materials in addition to the orientation as depicted in the figures. For example, if materials in the figures are inverted, elements described as “below” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (rotated ninety degrees, inverted, etc.) and the spatially relative descriptors used herein interpreted accordingly.

As used herein, the terms “level” and “elevation” are spatially relative terms used to describe one material's or feature's relationship to another material(s) or feature(s) as illustrated in the figures, using—as a reference point—the lowest illustrated surface of the structure that includes the materials or features. As used herein, a “level” and an “elevation” are each defined by a horizontal plane parallel to a primary surface of the substrate or base structure on or in which the structure (that includes the materials or features) is formed. When used with reference to the drawings, “lower levels” and “lower elevations” are relatively nearer to the bottom-most illustrated surface of the respective structure, while “higher levels” and “higher elevations” are relatively further from the bottom-most illustrated surface of the respective structure.

As used herein, the term “depth” is a spatially relative term used to describe one material's or feature's relationship to other material(s) or feature(s) as illustrated in the figures, using—as a reference point—the highest illustrated surface of the structure (e.g., stack structure) that includes the materials or features. When used with reference to the drawings, a “depth” is defined by a horizontal plane parallel to the highest illustrated surface of the structure (e.g., stack structure) that includes the materials or features.

As used herein, the terms “shallow” and “deep” are elevationally relative terms used to describe one material's or feature's relationship to other material(s) or feature(s) as illustrated in the figures, such that a “shallow” or “shallower” stadium may occupy generally higher elevations of a stack and be formed in an elevationally higher group of tiers of the stack than a “deep” or “deeper” stadium. In such circumstance, the openings of the stadiums may be at the top, elevationally-high portion of the stack. A “shallow” stadium may define a lesser opening-in-stack volume above its staircase(s) than the opening-in-stack volume defined by a “deep” stadium.

Unless otherwise specified, any spatially relative terms used in this disclosure are intended to encompass different orientations in addition to the orientation as depicted in the drawings. For example, the materials in the drawings may be inverted, rotated, etc., with the “upper” levels and elevations then illustrated proximate the bottom of the page, the “lower” levels and elevations then illustrated proximate the top of the page, the greatest “depths” extending a greatest vertical distance upward, and the “deep” stadiums being elevationally higher than the “shallow” stadiums.

As used herein, the terms “comprising,” “including,” “having,” and grammatical equivalents thereof are inclusive, open-ended terms that do not exclude additional, unrecited elements or method steps. These terms also include more restrictive terms “consisting of” and “consisting essentially of” and grammatical equivalents thereof. Therefore, a structure described as “comprising,” “including,” and/or “having” a material may be a structure that, in some embodiments, includes additional material(s) as well and/or a structure that, in some embodiments, does not include any other material(s). Likewise, a material (e.g., composition) described as “comprising,” “including,” and/or “having” a species may be a material that, in some embodiments, includes additional species as well and/or a material that, in some embodiments, does not include any other species.

As used herein, the term “may” with respect to a material, structure, feature, or method act indicates that such is contemplated for use in implementation of an embodiment of the disclosure and such term is used in preference to the more restrictive term “is” so as to avoid any implication that other, compatible materials, structures, features, and methods usable in combination therewith should or must be excluded.

As used herein, “and/or” means and includes any and all combinations of one or more of the associated listed items.

As used herein, the singular forms “a,” “an,” and “the” are intended to include the plural forms as well, unless the context clearly indicates otherwise.

As used herein, an “(s)” at the end of a term means and includes the singular form of the term and/or the plural form of the term, unless the context clearly indicates otherwise.

As used herein, the terms “configured” and “configuration” mean and refer to a size, shape, material composition, orientation, and arrangement of a referenced feature (e.g., region, material, structure, opening, assembly, device) so as to facilitate a referenced operation or property of the referenced feature in a predetermined way.

The illustrations presented herein are not meant to be actual views of any particular material, structure, sub-structure, region, sub-region, device, system, or stage of fabrication, but are merely idealized representations that are employed to describe embodiments of the disclosure.

Embodiments are described herein with reference to cross-sectional illustrations that are schematic illustrations. Accordingly, variations from the shapes of the illustrations as a result, for example, of manufacturing techniques and/or tolerances, are to be expected. Thus, embodiments described herein are not to be construed as limited to the particular shapes or structures as illustrated but may include deviations in shapes that result, for example, from manufacturing techniques. For example, a structure illustrated or described as box-shaped may have rough and/or nonlinear features. Moreover, sharp angles that are illustrated may be rounded; surfaces and features illustrated to be vertical may be non-vertical, bent, and/or bowed; and/or structures illustrated with consistent transverse widths and/or lengths throughout the height of the structure may taper in transverse width and/or length. Thus, the materials, features, and structures illustrated in the figures are schematic in nature and their shapes are not intended to illustrate the precise shape of a material, feature, or structure and do not limit the scope of the present claims.

The following description provides specific details, such as material types and processing conditions, to provide a thorough description of embodiments of the disclosed apparatus (e.g., devices, systems) and methods. However, a person of ordinary skill in the art will understand that the embodiments of the apparatus and methods may be practiced without employing these specific details. Indeed, the embodiments of the apparatus and methods may be practiced in conjunction with conventional semiconductor fabrication techniques employed in the industry.

The fabrication processes described herein do not form a complete process flow for processing apparatus (e.g., devices, systems) or the structures thereof. The remainder of the process flow is known to those of ordinary skill in the art. Accordingly, only the methods and structures necessary to understand embodiments of the present apparatus (e.g., devices, systems) and methods are described herein.

Unless the context indicates otherwise, the materials described herein may be formed by any suitable technique including, but not limited to, spin coating, blanket coating, chemical vapor deposition (“CVD”), atomic layer deposition (“ALD”), plasma enhanced ALD, physical vapor deposition (“PVD”) (e.g., sputtering), or epitaxial growth. Depending on the specific material to be formed, the technique for depositing or growing the material may be selected by a person of ordinary skill in the art.

Unless the context indicates otherwise, the removal of materials described herein may be accomplished by any suitable technique including, but not limited to, etching (e.g., dry etching, wet etching, vapor etching), ion milling, abrasive planarization, or other known methods.

In referring to the drawings, like numerals refer to like components throughout. The drawings are not necessarily drawn to scale.

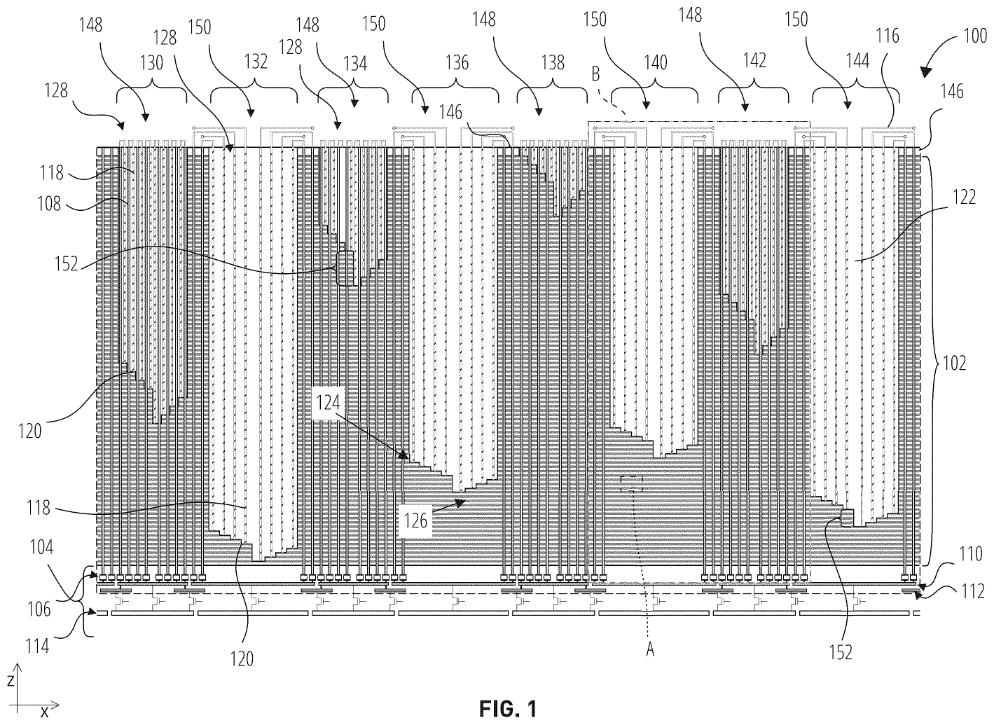

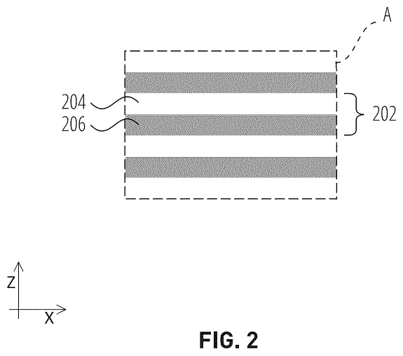

With reference to FIG. 1, illustrated is a microelectronic device structure 100 that includes a stack 102 (which may otherwise be referred to herein as a “stack structure” or as a “tiered stack”) of material structures, which are illustrated in greater detail in FIG. 2. FIG. 2 is an enlargement of the area of box “A” of FIG. 1 and may be equally illustrative of other portions of the stack 102. The stack 102 (FIG. 1) has materials arranged in tiers 202 that are vertically repeated through at least a portion (e.g., a majority) of the stack 102. Some or all of the tiers 202 individually include at least one insulative structure 204 and at least one conductive structure 206. In some embodiments, each tier 202 includes a single one of the insulative structures 204 and a single one of the conductive structures 206 vertically neighboring the one of the insulative structures 204 to provide a vertically alternating, interleaved arrangement of the insulative structures 204 and the conductive structures 206.

The number (e.g., quantity) of tiers 202 (and conductive structures 206) illustrated in FIG. 1 and other figures is for example only, and the disclosure is not so limiting. For example, a microelectronic device structure, in accordance with embodiments of the disclosure, may include a different quantity of the tiers 202 (e.g., and of the conductive structures 206) in the stack 102. In some embodiments, the stack 102 includes one-hundred twenty-six or one-hundred twenty-eight of the tiers 202 (and of the conductive structures 206). The number (e.g., quantity) of the tiers 202—and therefore of the conductive structures 206—of the stack 102 may be within a range of from thirty-two to three-hundred or more. The tiers 202 may be included in one or more decks of the stack 102.

The conductive structures 206 may be formed of and include (e.g., each be formed of and include) one or more conductive materials, such as one or more of: at least one metal (e.g., one or more of tungsten, titanium, nickel, platinum, rhodium, ruthenium, iridium, aluminum, copper, molybdenum, silver, gold), at least one alloy (e.g., an alloy of one or more of the aforementioned metals), at least one metal-containing material that includes one or more of the aforementioned metals (e.g., metal nitrides, metal silicides, metal carbides, metal oxides, such as a material including one or more of titanium nitride (TiN), tantalum nitride (TaN), tungsten nitride (WN), titanium aluminum nitride (TiAlN), iridium oxide (IrOₓ), ruthenium oxide (RuOₓ), alloys thereof), at least one conductively-doped semiconductor material (e.g., conductively-doped silicon, conductively-doped germanium, conductively-doped silicon germanium), polysilicon, and at least one other material exhibiting electrical conductivity. In some embodiments, the conductive structures 206 include at least one of the aforementioned conductive materials along with at least one additional of the aforementioned conductive materials formed as a liner. Some or all of the conductive structures 206 may have the same (e.g., consistent) or different thicknesses (e.g., heights) as one another.

The insulative structures 204 may be formed of and include (e.g., each be formed of and include) at least one insulative material, such as a dielectric oxide material (e.g., silicon dioxide). In this and other embodiments described herein, the insulative material of the insulative structures 204 may be substantially the same as or different than other insulative material(s) of the microelectronic device structure 100. Some or all of the insulative structures 204 may have the same (e.g., consistent) or different thicknesses (e.g., heights) as one another. In some embodiments, some of the insulative structures 204 (e.g., uppermost, lowest, and/or intermediate insulative structures 204) are relatively thicker than others of the insulative structures 204 of the stack 102.

With continued reference to FIG. 1, the stack 102 may be provided on or over a base region 104, which may include one or more regions formed of and including, for example, one or more semiconductor materials (e.g., polycrystalline silicon (polysilicon)) doped with one or more P-type conductivity chemical species (e.g., one or more of boron, aluminum, and gallium) and/or one or more N-type conductivity chemical species (e.g., one or more of arsenic, phosphorous, and antimony) to provide one or more source/drain regions of the microelectronic device structure 100.

In addition to the semiconductor materials and/or source/drain region, the base region 104 may include other base material(s), region(s), and/or structure(s), such as conductive regions for making electrical connections with other conductive structures of the device that includes the microelectronic device structure 100. In some such embodiments, CMOS (complementary metal-oxide-semiconductor) circuitry is included within the base region 104, in a CMOS region below the source/drain region, which CMOS region may be characterized as a so-called “CMOS under Array” (“CuA”) region.

The base region 104 may include conductive landings 106 to which through-stack vias 108 extend. For through-stack vias 108 that are configured to be electrically “active” during operation of the microelectronic device that includes the microelectronic device structure 100, the corresponding conductive landings 106 may be in electrical communication with routing (e.g., first under routing 110 and/or second under routing 112), which may be within the CMOS region. The routing (e.g., first under routing 110 and second under routing 112) may be in electrical communication with string drivers 114, which may also be within the CMOS region of the base region 104. The through-stack vias 108 may also be in electrical communication (e.g., via upper routing 116 above the stack 102) with respective step contacts 118 that physically and electrically connect with the conductive structures 206 (FIG. 2) of the stack 102. As discussed further below, this configuration enables the string drivers 114 to effectively drive electrical current to the conductive structures 206, via the under routing (first under routing 110 and/or second under routing 112), the conductive landings 106, the through-stack vias 108, the upper routing 116, and the step contacts 118. The through-stack vias 108 may extend substantially vertically through all or substantially all the elevations of the stack 102; whereas, the step contacts 118 may extend substantially vertically through some elevations of the stack 102, such as the elevations of the stack 102 that are at or above the conductive structure 206 (FIG. 2) of the tier 202 (FIG. 2) and/or step to which the respective step contact 118 extends.

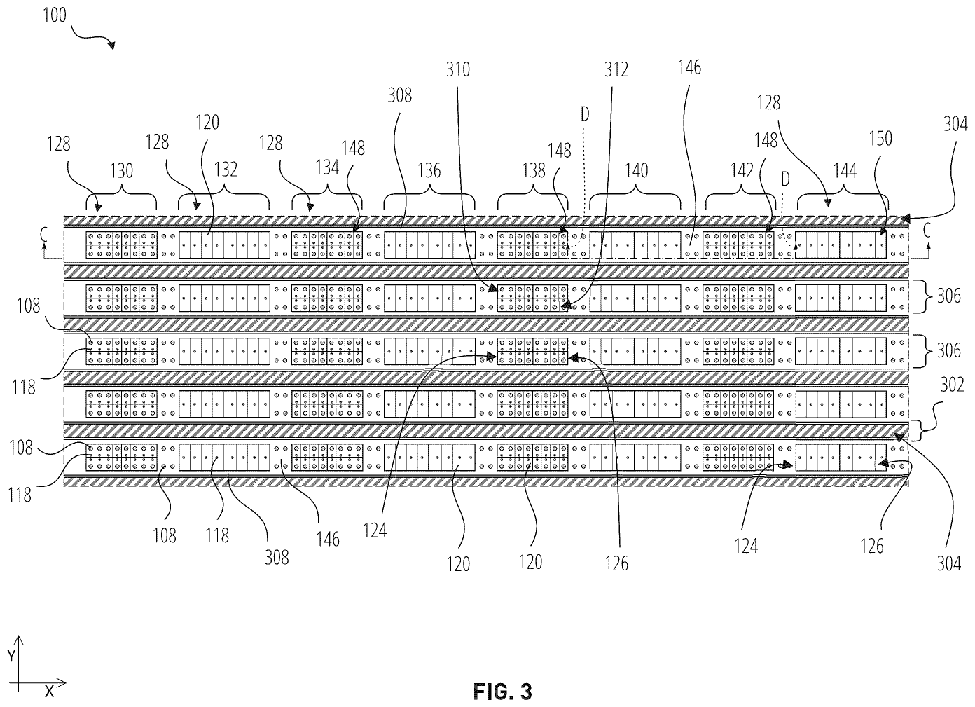

With continued reference to FIG. 1 and also with reference to FIG. 3—which is a top plan view of a microelectronic device that may include the microelectronic device structure 100 of FIG. 1 and may include the tiers 202 of FIG. 2—a series of slit structures 302 (or other elongate structures) formed in slits 304 extends through the stack 102 to divide the stack 102 into a series of blocks 306. Each block 306 extends in the lateral direction (e.g., with a greater dimension (e.g., width) in the “X”-axis direction than a dimension (e.g., length) in the “Y”-axis direction). A pair of the slits 304 may be formed, parallel to the “X”-axis, to define the front and rear of a respective one of the blocks 306 of the microelectronic device structure 100.

The slit structures 302 may individually include one or more non-conductive material(s) substantially filling the slits 304. In some embodiments, each slit structure 302 includes at least one non-conductive material (e.g., silicon, insulative material) lined by one or more other non-conductive material(s) (e.g., other insulative material(s)).

Other portions of the microelectronic device structure 100 (e.g., portions horizontally disposed relative to the portions illustrated in, e.g., FIG. 1 and FIG. 3) may include array(s) of pillars (e.g., including channel material and memory material) extending through the stack 102 and to and/or into the base region 104 (e.g., to and/or into a source/drain region). The pillars may effectuate the formation of strings of memory cells of a memory device (e.g., a memory device including any of the microelectronic device structures described or illustrated herein). The conductive structures 206 (FIG. 2) of the tiers 202 may be coupled to, or may form control gates of, the memory cells effectuated by the pillars. For example, each conductive structure 206 of the stack 102 (FIG. 1) may be coupled to an individual memory cell of a particular string (e.g., effectuated by a particular pillar) of memory cells.

To facilitate electrical communication to particular selected conductive structures 206 within the stack 102, conductive contact structures (the step contacts 118) extend to (or from) and physically contact the conductive structures 206 of the tiers 202. Each such step contact 118 is positioned to physically contact a particular one of the conductive structures 206, namely one of the conductive structures 206 that is in one of the tiers 202 that has been patterned and/or partially exposed to provide a step 120. Herein, a tier 202 providing one of the steps 120 may be referred to as a “stepped tier.”

The step 120 includes a tread in the form of an exposed upper (e.g., horizontal) surface portion of one of the material structures of the tier 202. The tread of the step 120 defines a landing area for one of the step contacts 118.

In some embodiments, the tread of the step 120 is defined by an exposed upper surface portion of an uppermost insulative structure 204 of the stepped tier 202, and the step contact 118 extends through this insulative structure 204 to reach one of the conductive structures 206 of the stepped tier 202. The step contact 118 may or may not include an insulative liner horizontally around conductive material of the step contact 118.

In other embodiments, the tread of the step 120 is defined by an exposed upper surface portion of an uppermost conductive structure 206 of the stepped tier 202, and the step contact 118 extends to or into this uppermost conductive structure 206 of the stepped tier 202. The step contact 118 may or may not include an insulative liner horizontally around conductive material of the step contact 118.

In other embodiments, the tread of the step 120 is defined by an exposed upper surface portion of an uppermost conductive structure 206 of the stepped tier 202, and the step contact 118 extends through the uppermost conductive structure 206 and to or into a lower conductive structure 206 of the tier 202 providing the step 120. The step contact 118 may be electrically isolated from upper conductive structure(s) 206 through which it extends by, e.g., an insulative liner horizontally around conductive material(s) of the step contact 118.

With continued reference to FIG. 1, to provide the steps 120, the stack 102 is patterned (e.g., etched) to expose one or more upper (e.g., horizontal) surface area portion(s) of individual tiers 202 (FIG. 2), such as upper (e.g., horizontal) surface area portion(s) of individual insulative structures 204 of the stack 102. That is, the tiers 202 are selectively patterned to remove portions of otherwise-overlying tiers 202 to leave exposed (until otherwise covered by non-conductive (e.g., insulative) fill material(s) (e.g., insulative fill regions 122), step contacts 118, through-stack vias 108, or other features) at least one upper surface area of a material structure (e.g., the uppermost insulative structure 204 or the uppermost conductive structure 206) of the tier 202 or tiers 202 to be “stepped.” Each exposed area provides one step 120.

Because individual conductive structures 206 and their respective tiers 202 in the stack 102 occupy different elevations of the stack 102 (also referred to herein as different “tier elevations”), the steps 120 are formed at the various elevations of the stack 102. Each step contact 118 extends downward to physically contact (e.g., “land” on or in) one of the conductive structures 206 of the tier 202 providing the respective step 120. Above the steps 120, the step contacts 118 may extend primarily through the insulative fill regions 122 (FIG. 1).

The vertical dimension (e.g., height) of an individual step contact 118 may be tailored according to the depth (e.g., elevation) of its respective target step 120. The step contacts 118 extending to steps 120 at relatively higher elevations of the stack 102, may be generally shorter than the step contacts 118 that extend to steps 120 at relatively lower elevations of the stack 102. The microelectronic device structure 100 may include, in each respective block 306 (FIG. 3), at least one step contact 118 per step 120 and, therefore, at least one step contact 118 per electrically-active conductive structure 206 of the stack 102.

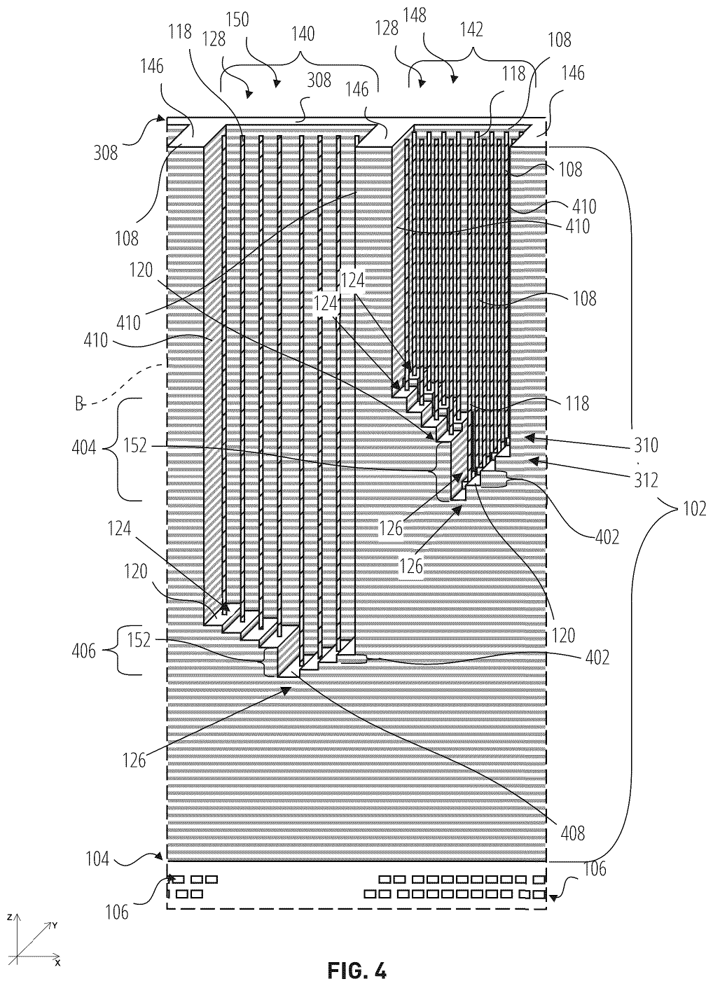

FIG. 4 is an enlarged view of the area of box “B” of FIG. 1, but without illustrating through-stack vias 108 and the insulative fill regions 122, for ease of viewing the step contacts 118 and the steps 120. The steps 120 are grouped in staircases (e.g., descending staircases 124, ascending staircases 126) with each staircase providing at least a part of a row (e.g., series) (extending in the X-axis direction) of the steps 120, all or at least some of which are at different tier elevations than others of the steps 120 in the staircase.

The tier elevations of the steps 120 of a respective staircase may incrementally decrease or incrementally increase through the staircase (e.g., descending staircase 124, ascending staircase 126) according to a “riser height” 402. For example, in one staircase, the steps 120 may be formed at successively increasing tier depths (e.g., decreasing tier elevations) to define a descending staircase 124 having generally negative slope. In another staircase, the steps 120 may be formed at successively decreasing tier depths (e.g., increasing tier elevations) to define an ascending staircase 126 having generally positive slope. The elevation difference between neighboring steps 120 of a respective staircase (e.g., one of the descending staircases 124, one of the ascending staircases 126) defines the riser height 402. As discussed further below, in some embodiments, one or more staircases of one of the blocks 306 (FIG. 3) define a riser height 402 different than the riser height 402 defined by another of the staircases of the block 306.

The staircases (e.g., the descending staircases 124 and the ascending staircases 126) are grouped in so-called “stadiums” 128. Each set of staircases extends the width of one of the stadiums 128. As used herein, a “set” of staircases comprises the one or more staircases that are horizontally aligned in the X-axis direction within a respective stadium 128 and that extend the width of the stadium 128.

As illustrated in FIG. 1 and FIG. 3, the stadiums 128—of a respective block 306 of the microelectronic device structure 100—may be arranged in a series such that multiple stadiums 128 are distributed across a width of the block 306 and extend, in a row (e.g., in the X-axis direction), substantially parallel to the slits 304 (FIG. 3) and to the slit structures 302 (FIG. 3). The block 306 (and stadium series) may include as many stadiums 128 as necessary to include at least one step 120 per tier 202 (and per conductive structure 206) of the stack 102 that is to be electrically active during operation of the microelectronic device.

In some embodiments, the steps 120 of the staircases (e.g., descending staircases 124 and/or ascending staircases 126) of a respective individual stadium 128 are formed in a unique group of the tiers 202 (FIG. 2) of the stack 102. For example, with continued reference to FIG. 4, one stadium 128 may have steps 120 defined in a first tier group 404, and another stadium 128 may have steps 120 defined in a second tier group 406 that is elevationally above or below the first tier group 404. Therefore, the steps 120 of both stadiums 128 may be elevationally unique within the stack 102.

In other embodiments, some of the stadiums 128 have steps 120 formed in a same tier group as one or more other stadiums 128 of the block 306, such that conductive structures 206 of steps 120 of such repeated stadiums 128 may provide more than one landing to accommodate more than one step contact 118.

With continued reference to FIG. 1 and FIG. 3, each stadium 128 may be formed in a different horizontal area of the block 306, such as in a first stadium area 130, a second stadium area 132, a third stadium area 134, a fourth stadium area 136, a fifth stadium area 138, a sixth stadium area 140, a seventh stadium area 142, an eighth stadium area 144, etc. As illustrated, each stadium 128 is defined in a unique tier group of the stack 102.

Laterally neighboring stadiums 128 may be spaced from one another, in the stadium series of the block 306 (FIG. 3), by a so-called “crest” area (crest 146) of the stack 102. The crests 146 may be formed by areas of the stack 102 where the stack 102 and its tiers 202 have not been patterned. The crests 146 may, therefore, extend an entire height of the stack 102. In some embodiments, uppermost boundaries of the crests 146 are positioned at (e.g., coplanar with) uppermost boundaries of the stack 102 or at uppermost boundaries of insulative material(s) above the stack 102.

As illustrated in FIG. 3 and FIG. 4, within an individual block 306, one or more other non-patterned portions of the stack 102 may form so-called “bridge” areas (bridges 308). As illustrated in FIG. 3, each bridge 308 may extend a width of the block 306. The bridges 308 may extend the entire height of the stack 102. In some embodiments, uppermost boundaries of the bridge 308 are positioned at (e.g., coplanar with) uppermost boundaries of the stack 102 or at uppermost boundaries of insulative material(s) above the stack 102. Each bridge 308 may border one of the slits 304 (and slit structures 302) that define the block 306 length (Y-axis dimension). In some embodiments, each block 306 includes two bridges 308, one at a front side and one at a rear side of the block 306. Each of the bridges 308 borders a different one of the slits 304 (and slit structures 302) that define the block 306, as illustrated in FIG. 3.

Via the one or more bridges 308 of the block 306, distal portions of a given conductive structure 206 of a respective tier 202 are part of a continuous, single conductive structure 206 of that tier 202 throughout the block 306. Therefore, an electrical connection between one of the step contacts 118 and a conductive structure 206 of one of the steps 120 may provide an electrical connection between the one step contact 118 and the whole of that conductive structure 206 throughout the block 306.

With returned reference to FIG. 1, one or more of the stadium 128 of the series in the block 306 (FIG. 3) may include multiple sets of parallel staircases. Such a stadium 128 is referred to herein as a “multi-set stadium” 148. One or more other of the stadiums 128 of the series in the block 306 may include a single set of staircases. Such a stadium 128 is referred to herein as a “single-set stadium” 150.

The multi-set stadiums 148 may be the relatively shallower (e.g., relatively elevationally higher) stadiums 128 of the block 306. The single-set stadiums 150 may be the relatively deeper (e.g., relatively elevationally lower) stadiums 128 of the block 306. Accordingly, the multi-set stadiums 148 may also be referred to herein as “shallow” stadiums 128, and the single-set stadiums 150 may also be referred to herein as “deep” stadiums 128.

In a single-set stadium 150, the tread of each step 120 may span substantially a whole length (Y-axis dimension) of the stadium 128 (FIG. 3), such as in the single-set stadium 150 in the sixth stadium area 140, illustrated in enlarged form in FIG. 4. In a multi-set stadium 148, the tread of each step 120 may span only a portion (e.g., about half) of the whole length (Y-axis dimension) of the stadium 128 (FIG. 3), such as in the multi-set stadium 148 in the seventh stadium area 142, as illustrated in enlarged form in FIG. 4.

In each multi-set stadium 148, the multiple sets of staircases define multiple rows (and sets) of staircases, and therefore multiple rows of steps 120 (one row per set). Multiple rows of step contacts 118 may extend to the conductive structures 206 of the steps 120 of the multi-set stadiums 148, as in the multi-set stadium 148 in the seventh stadium area 142, as illustrated in FIG. 4. With multiple sets of parallel staircases in the multi-set stadium 148, the multi-set stadium 148 provides multiple more (e.g., twice as many) steps 120, and accommodates connection to multiple more (e.g., twice as many) step contacts 118 (FIG. 4), compared to one of the single-set stadiums 150. The single-set stadiums 150 may have a single staircase set (e.g., a single row of steps 120) and may be associated with a single row of step contacts 118, as in the single-set stadium 150 in the sixth stadium area 140, as illustrated in FIG. 4.

In some embodiments including both multi-set stadiums 148 and single-set stadiums 150 in the block 306, the multi-set stadiums 148 are interspersed with one another so that the stadium 128 depths across the width of the block 306 vary between shallow stadiums (e.g., multi-set stadiums 148) and deep stadiums (e.g., single-set stadiums 150). For example, as illustrated in FIG. 1 and FIG. 3, one multi-set stadium 148 may be laterally disposed between two single-set stadiums 150, and one single-set stadium 150 may be laterally be disposed between two multi-set stadiums 148. In other embodiments, rather than being interspersed, some or all of the single-set stadiums 150 may be laterally neighbored to one another, and some or all of the multi-set stadiums 148 may be laterally neighbored to one another, such as to provide a series of stadiums with increasing or decreasing stadium 128 depth across the width of the block 306.

In some embodiments, the horizontal area (e.g., footprint of the stack 102) occupied by individual of the multi-set stadiums 148 is about the same as the horizontal area (e.g., footprint of the stack 102) occupied by individual of the single-set stadiums 150. In other embodiments, the multi-set stadiums 148 (shallow stadiums 128) individually occupy a somewhat smaller width and smaller horizontal area than that of the single-set stadiums 150. In some such embodiments, a landing area 408 (e.g., lowest step 120 of the single-set stadium 150) may be relatively wider than other steps 120 of the single-set stadium 150. The increased width of the single-set stadium 150 (e.g., deep stadiums 128) compared to the multi-set stadiums 148 (e.g., shallow stadiums 128) may accommodate accurate fabrication of the single-set stadium 150 at relatively deeper elevations of the stack 102, where accurately fabricating high-aspect-ratio stadium openings may present challenges.

With continued reference to FIG. 4, the multiple sets of staircases of the multi-set stadium 148 may be provided by multiple parallel rows of steps 120 (e.g., multiple parallel staircases), such as by two sets of staircases: one upper staircase set 310 and one lower staircase set 312. Each set of staircases (e.g., the upper staircase set 310 and the lower staircase set 312) may include at least one descending staircase 124 and/or at least one ascending staircase 126. In some embodiments, each set of staircases includes a single descending staircase 124 and a single ascending staircase 126. In other embodiments, more than two sets of parallel staircases are included, and/or each set consists of only a single staircase (e.g., a single ascending staircase 126 or a single descending staircase 124).

In each multi-set stadium 148 (e.g., the multi-set stadium 148 in the seventh stadium area 142, illustrated in enlarged view in FIG. 4), each of the steps 120 of the staircases (e.g., of the upper staircase set 310 and of the lower staircase set 312) occupy a unique tier elevation compared to the other steps 120 of the multi-set stadium 148. To accomplish this, the neighboring staircase sets (e.g., the upper staircase set 310, the lower staircase set 312) may be vertically offset from one another by at least a height of one tier 202, and the riser height 402 within each staircase may be the height of two tiers 202. Thus, in an embodiment in which each staircase includes four steps (as a non-limiting example), if the uppermost step 120 of the upper staircase set 310 is defined as tier elevation “N” of the group of tiers in which the stadium 128 is defined (first tier group 404), the tier elevations of the remaining steps of the descending staircase 124 of the upper staircase set 310 would be N-2, N-4, and N-6; and the steps 120 of the descending staircase 124 of the lower staircase set 312 would be N-1, N-3, N-5, and N-7. In embodiments in which the descending staircases 124 descend toward the ascending staircases 126, the descending staircases 124 may be vertically offset from ascending staircases 126 (e.g., by vertical offset 152) to further enable the steps 120 of the ascending staircases 126 of the lower staircase set 312 and the upper staircase set 310 to be at unique tier elevations within the group of tiers 202 (first tier group 404) in which the multi-set stadium 148 is formed. For example, again in the embodiment discussed above in which each staircase includes four steps (as a non-limiting example), the steps 120 of the ascending staircase 126 of the upper staircase set 310 may be at elevations N-14, N-12, N-10, and N-8, respectively; and the steps 120 of the ascending staircase 126 of the lower staircase set 312 may be at elevations N-15, N-13, N-11, and N-9.

In each single-set stadium 150 (e.g., the single-set stadium 150 in the sixth stadium area 140, illustrated in enlarged view in FIG. 4), each of the steps 120 of the staircases also occupy a unique tier elevation compared to other steps 120 of that single-set stadium 150. To accomplish this, the riser height 402 within each staircase (e.g., the descending staircase 124 and the ascending staircase 126) may be the height of one tier 202. In embodiments in which the descending staircase 124 descends toward the ascending staircase 126, the descending staircase 124 may be vertically offset from the ascending staircase 126 (e.g., by vertical offset 152) to further enable the steps 120 of the ascending staircase 126 to be at unique tier elevations within the group of tiers 202 (second tier group 406) in which the single-set stadium 150 is defined. For example, in an embodiment in which each staircase includes four steps (as a non-limiting example), the steps 120 of the single-set stadium 150 may be at elevations N, N-1, N-2, N-3, N-7, N-6, N-5, N-4, respectively, wherein “N” defines the tier elevation of the uppermost step 120 of the tier group in which the stadium 128 is defined (e.g., second tier group 406).

In some embodiments, each set of staircases (e.g., the single set of staircases of the single-set stadium 150; and the upper staircase set 310 and the lower staircase set 312 of the multi-set stadium 148) is provided by a single descending staircase 124 or by a single ascending staircase 126, such that the vertical offset(s) 152 may be omitted.

Though the figures, like FIG. 4, illustrate staircases respectively including four steps 120, the disclosure is not so limited. Any other number (e.g., quantity) of steps 120 may be included in an individual staircase and in an individual staircase set. For example, an individual staircase may include six, seven, eight, or more than eight of the steps, and an individual staircase set may include twelve, fourteen, sixteen, or more than sixteen of the steps. In some embodiments, one or more individual staircase(s) of a staircase set may include an odd number of steps 120, such that a descending staircase 124 may have one (+1), three (+3), five (+5), etc., greater number of steps 120 than a corresponding ascending staircase 126, or vice versa. For an individual stadium 128, the number of steps 120 in the descending staircase(s) 124 thereof may or may not be the same as the number of steps 120 in the ascending staircase(s) 126 thereof.

In some embodiments, the steps 120 of respective staircases are of consistent horizontal area. In other embodiments, one or more of the steps 120 of a respective staircase may be of a different horizontal area. For example, with reference to FIG. 4, the landing area 408 providing the lowest step 120 of the single-set stadium 150 may be somewhat wider (X-axis dimension) than the other steps 120 of the single-set stadium 150.

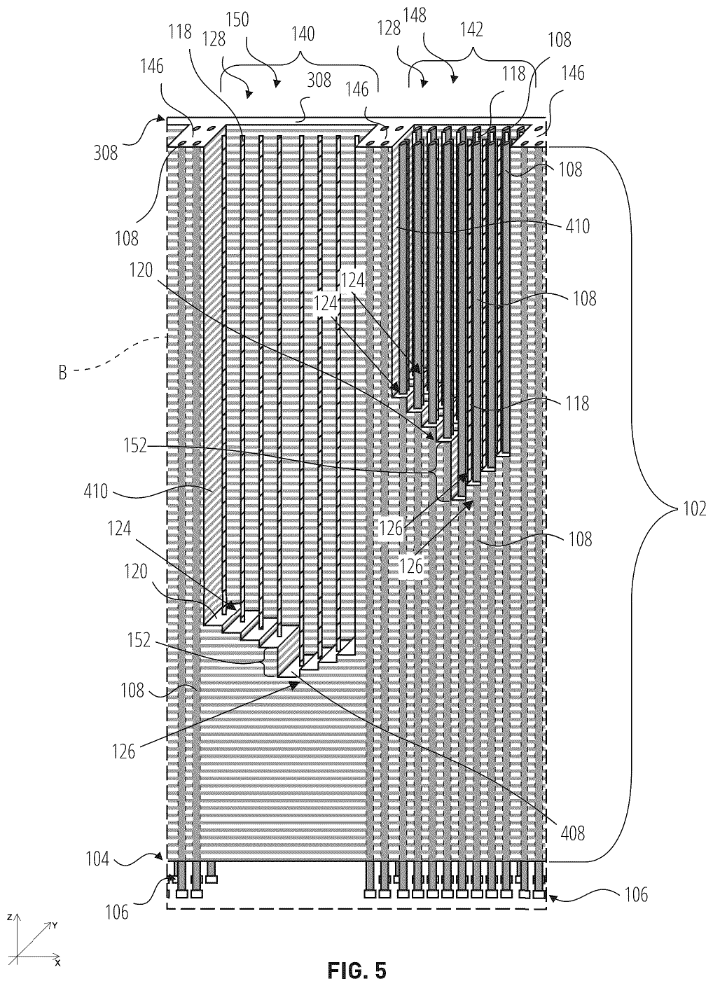

With continued reference to FIG. 1 and with reference to the enlarged illustration in FIG. 5, the microelectronic device structure 100 also includes through-stack conductive structures (the through-stack vias 108), which extend substantially vertically through a whole height of the stack 102 and to the conductive landings 106 in the base region 104. As discussed further below, electrically active (referred to herein as “active”) through-stack vias 108 also connect with other electrically active conductive features—such as upper conductive regions and/or routing—to electrically communicate with the step contacts 118. In some embodiments, additional through-stack conductive structures are included in the microelectronic device structure 100 as non-electrically functional (e.g., “non-active,” “dummy,” and/or “support”) structures. Such non-electrically functional, through-stack conductive structures may be electrically and/or physically isolated from (and may not be in physical or electrical connection with) the upper conductive regions and/or routing to which the “active” through-stack vias 108 connect. Unless otherwise indicated herein, reference to “through-stack vias” 108 means “active” through-stack vias 108; whereas reference to “support contacts” means “non-electrically functional” structures, which may be of the same general composition and/or structure (e.g., height) as the active through-stack vias 108.

In some embodiments, the through-stack vias 108, whether active or non-active, may include at least one insulative liner horizontally around conductive material(s) to electrically isolate the conductive material(s) from neighboring conductive feature(s). For example, where the through-stack vias 108 extend through the tiers 202 (FIG. 2) of the stack 102, the through-stack vias 108 may be electrically isolated from the conductive structures 206 of the stack 102 by one or more insulative liners.

A single active through-stack via 108 may be in electrical communication with a single step contact 118. Thus, there may be one active through-stack via 108 for every step contact 118 (and every step 120).

According to embodiments of the disclosure, the through-stack vias 108 associated with the step contacts 118 of multi-set stadiums 148 (e.g., shallow stadiums 128) are disposed within the horizontal area of the multi-set stadium 148 (shallow stadium 128) itself. As illustrated most clearly in the top plan view of FIG. 3 and the view of FIG. 5, each such through-stack via 108 may be within the horizontal area of, and extend vertically through, one of the steps 120 of the multi-set stadiums 148.

Also according to embodiments of the disclosure, the majority of the through-stack vias 108 associated with the step contacts 118 of the single-set stadiums 150 (e.g., deep stadiums 128) are disposed in the crests 146 to the lateral sides of the single-set stadium 150 (e.g., deep stadium 128).

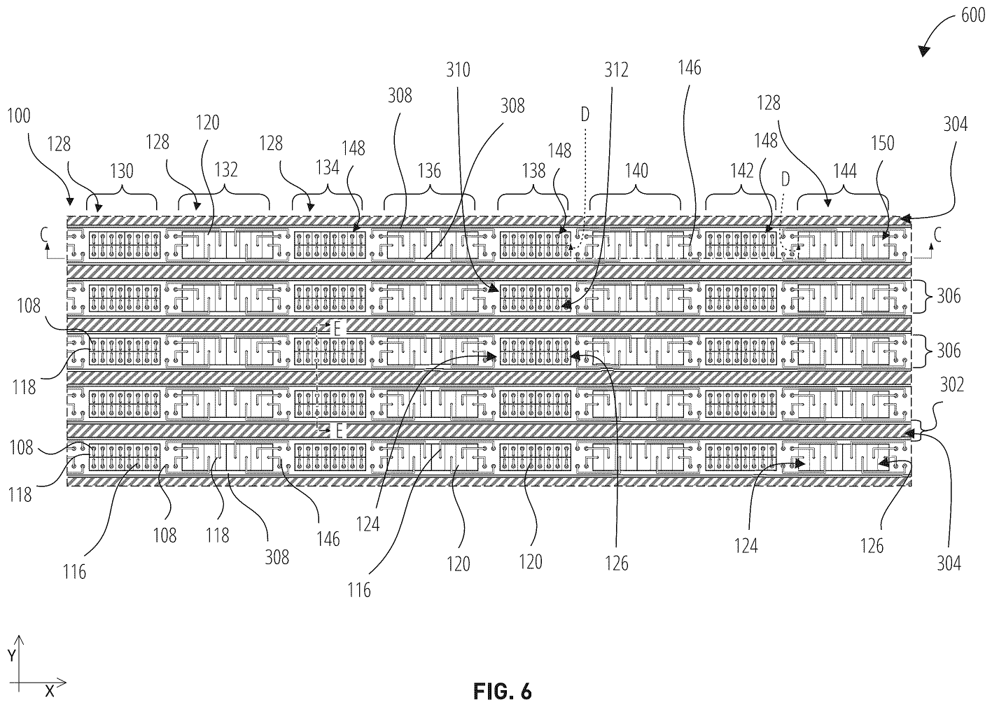

With reference to FIG. 6, upper routing 116 is schematically illustrated to show the respective electrical connections between each through-stack via 108 and its associates step contact 118. Accordingly, for the multi-set stadiums 148 (e.g., shallow stadiums 128), the upper routing 116 may be substantially within the horizontal area of the stadium 128, with substantially direct-line routing (upper routing 116) between the step contact 118 of a particular step 120 and the through-stack via 108 that extends through that same step 120. For the single-set stadiums 150 (e.g., deep stadiums 128), the upper routing 116 may extend from the step contacts 118 within the horizontal area of the stadium 128 to the through-stack vias 108 within the horizontal area of one (or both) of the crests 146. This within-stadium upper routing 116 for the multi-set stadiums 148 (e.g., shallow stadiums 128) and the stadium-to-crest upper routing 116 for the single-set stadiums 150 (e.g., deep stadiums 128) is also schematically illustrated in FIG. 1.

This disclosure is not limited to the upper routing 116 pattern illustrated. Other upper routing 116 arrangements may be used to electrically connect the through-stack vias 108 with their respective step contacts 118.

By disposing the through-stack vias 108 of the deep stadiums 128 (e.g., the single-set stadiums 150) within the crests 146, these through-stack vias 108 extend substantially wholly through materials of the stack 102, from which they are electrically isolated (e.g., by liner(s)). Thus, the through-stack vias 108 associated with the deep, single-set stadiums 150 may not extend through the insulative fill region 122 (FIG. 1) overlying the staircases (e.g., descending staircases 124, ascending staircases 126) of the stadiums 128. The through-stack vias 108 of the deep, single-set stadiums 150 may also be disposed away from sidewalls 410 (FIG. 4 and FIG. 5) that define the openings above the single-set stadiums 150, which may accommodate forming the through-stack vias 108 accurately and in reliable contact with their respective conductive landings 106 (FIG. 1) below the stack 102. That is, in fabricating deep stadiums 128, the sidewalls 410 may tend to exhibit certain structural defects, such as bowing, twisting, leaning, etc., as a result of differences in residual material stresses and strains between the materials of the stack 102 and the materials of the insulative fill region 122. These stresses and strains—and therefore the resulting structural defects of the sidewalls 410—may be more pronounced the taller the sidewall 410 is. Therefore, the deep stadiums 128 (e.g., the single-set stadiums 150) may tend to exhibit more sidewall 410 deformations than the shallow stadiums 128 (e.g., the multi-set stadiums 148). Forming through-stack vias 108 within deep stadiums 128 (e.g., single-set stadiums 150) adjacent sidewalls 410 that have deformations may lead to the through-stack vias 108, themselves, exhibiting bending, bowing, leaning, twisting, or other structural defects. As such, the sidewalls 410 may protrude somewhat into the insulative fill regions 122 (in the space above the deep stadiums 128) and toward the through-stack vias 108. This may lead to the through-stack vias 108 not correctly “landing” on their respective, target conductive landings 106 in the base region 104. Thus, if one were to form the through-stack vias 108 of deep stadiums 128 (e.g., the single-set stadiums 150) within the horizontal area of the deep stadium 128 (e.g., the single-set stadium 150), accurate and reliable formation of the through-stack vias 108 may be relatively more challenging than accurately and reliably forming the through-stack vias 108 of the shallow stadiums 128 (e.g., the multi-set stadiums 148) within the horizontal area of the shallow stadium 128 (e.g., the multi-set stadium 148). According to embodiments of this disclosure, by disposing the through-stack vias 108 of the deep, single-set stadiums 150 within the crests 146, interference with sidewalls 410 exhibiting structural deformations may be avoided, and the through-stack vias 108 associated with the deep, single-set stadiums 150 may be more reliably and accurately formed.

To accommodate the crests 146 of the block 306 having a small horizontal area (e.g., footprint)—in the interest of device scaling—the through-stack vias 108 associated with the shallow, multi-set stadiums 148 may not be disposed within the crests 146, but may be disposed within the horizontal area of the shallow, multi-set stadiums 148 themselves. Because these stadiums 128 are relatively shallower than the deep, single-set stadiums 150, their sidewalls 410 (FIG. 4) may have less likelihood of exhibiting deformations, such that the through-stack vias 108 may be relatively less challenging to accurately and reliably form in electrical and physical communication with their respective conductive landings 106 (FIG. 1).

FIG. 6 illustrates a microelectronic device structure 600 that includes the microelectronic device structure 100 of FIG. 1 and in which all through-stack vias 108 (active) associated with the deep, single-set stadiums 150 are disposed within the crests 146. Such embodiments may further include additional, non-active through-stack vias to provide structural support to the microelectronic device structure 600. Such non-active through-stack vias may be, for example, disposed within the crests 146, disposed within the stadiums 128, disposed in an area that extends through the sidewalls 410 (FIG. 4), and/or disposed elsewhere within the block 306.

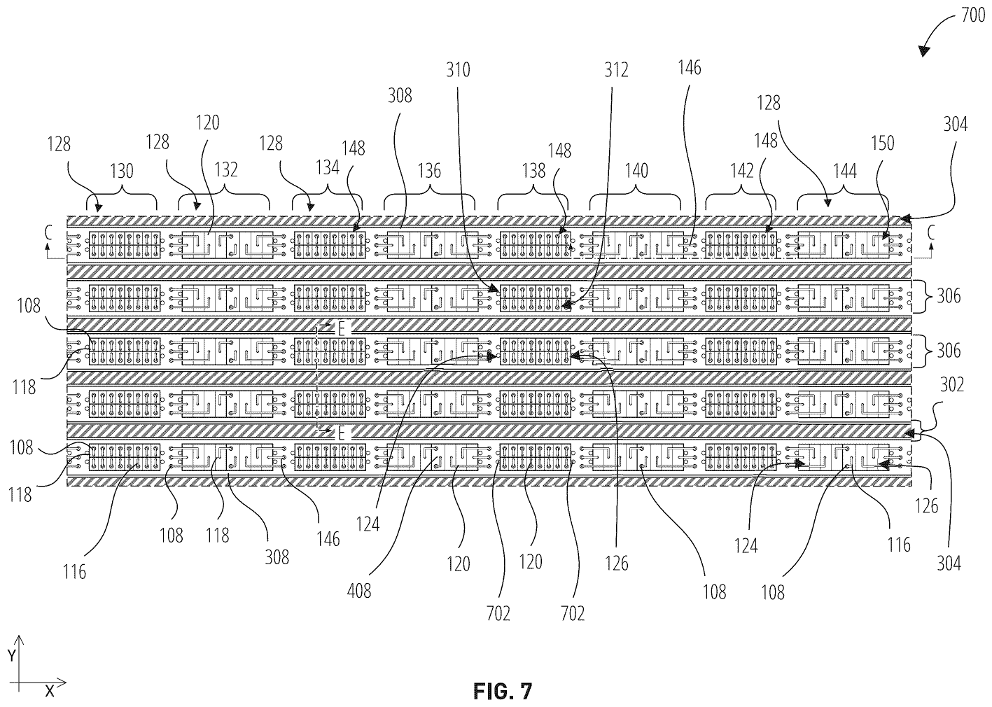

FIG. 7 illustrates a microelectronic device structure 700 that includes the microelectronic device structure 100 of FIG. 1, but with a different arrangement of the through-stack vias 108, wherein the majority of the through-stack vias 108 (active) associated with the deep, single-set stadiums 150 are disposed within the crests 146, but wherein some through-stack vias 108 (active) are disposed within the horizontal area of one or more steps 120 of the deep, single-set stadiums 150. For example, as illustrated in FIG. 7, one or more (e.g., two or more) of the through-stack vias 108 (active) associated with a respective deep, single-set stadiums 150 are disposed within the horizontal area of the lowest step 120 (e.g., the landing area 408) of that single-set stadium 150. Disposing one or more, but not all (e.g., not most), of the through-stack vias 108 (active) of the deep, single-set stadiums 150 in the landing area 408 of the single-set stadium 150 may provide the crests 146 being occupied by fewer active through-stack vias 108. In some embodiments, the horizontal area of the crests 146 not occupied by active through-stack vias 108 instead include support contacts 702. In some such embodiments, the support contacts 702 are included near the sidewalls 410 (FIG. 4) of the deep, single-set stadiums 150 to provide structural support. Accordingly, non-electrically active, support contacts 702 (e.g., conductive structures extending through a whole height of the stack 102 (FIG. 1) and, e.g., through substantially all elevations of the stack 102 (FIG. 1)) may be disposed in the crests 146 and may be horizontally between active through-stack vias 108 in the crests 146 and sidewalls 410 (FIG. 4) of the stadium 128 (the deep, single-set stadium 150).

To accommodate one or more active through-stack vias 108 in the landing area 408 of the deep, single-set stadium 150, the lowest step 120 providing the landing area 408 may be somewhat wider (in the X-axis direction) than other steps 120 of the single-set stadium 150. In some such embodiments, the single-set stadiums 150 are be individually relatively wider than individual multi-set stadiums 148.

With continued reference to FIG. 1, the string drivers 114 and the routing (e.g., first under routing 110, second under routing 112) electrically connecting the string drivers 114 to the conductive landings 106 (and, therefore, to the active through-stack vias 108) may have an arrangement tailored according to the arrangement of the various stadiums (e.g., the multi-set stadiums 148 and the single-set stadiums 150) in the series of stadiums 128. In the arrangement of the microelectronic device structure 100 of FIG. 1—wherein the multi-set stadiums 148 (in the first stadium area 130, the third stadium area 134, the fifth stadium area 138, and the seventh stadium area 142) are laterally interposed within the single-set stadiums 150 (in the second stadium area 132, the fourth stadium area 136, the sixth stadium area 140, and the eighth stadium area 144)—the string drivers 114 associated with the multi-set stadiums 148 may be laterally interposed with the string drivers 114 associated with the single-set stadiums 150. Because the multi-set stadiums 148 support a greater number of (e.g., twice as many) step contacts 118 than supported in the single-set stadiums 150, the group of string drivers 114 for the multi-set stadiums 148 may be relatively horizontally wider than the group of string drivers 114 for the single-set stadiums 150. Multiple levels (e.g., elevations) of routing (e.g., the first under routing 110 and the second under routing 112) may be included (e.g., vertically between the conductive landings 106 and the string drivers 114) to enable efficient electrical connections between the string drivers 114 and their respective through-stack vias 108.

The string drivers 114 (e.g., access line drivers, word line drivers) may be configured to selectively supply-via the under routing (e.g., the first under routing 110, the second under routing 112), the conductive landings 106, the through-stack vias 108, the upper routing 116, and the step contacts 118 leading to the steps 120—access signals, such as programming signals (e.g., programming voltages) to the conductive structures 206 (FIG. 2) (e.g., to access lines, also known as “word lines”) of the steps 120, at particular levels of the stack 102, so as to access (e.g., program) the memory cell(s) (e.g., in the array portions) that are operatively associated with respective conductive structures 206. There may be one string driver 114 coupled to one respective conductive structure 206 (e.g., access line), such that the microelectronic device structure 100 (FIG. 1) (or microelectronic device structure 600 of FIG. 6, or microelectronic device structure 700 of FIG. 7) may include one string driver 114 for each respective stepped tier 202 (e.g., each respective conductive structure 206 that is a step contact 118 landing associated with at least one step 120).

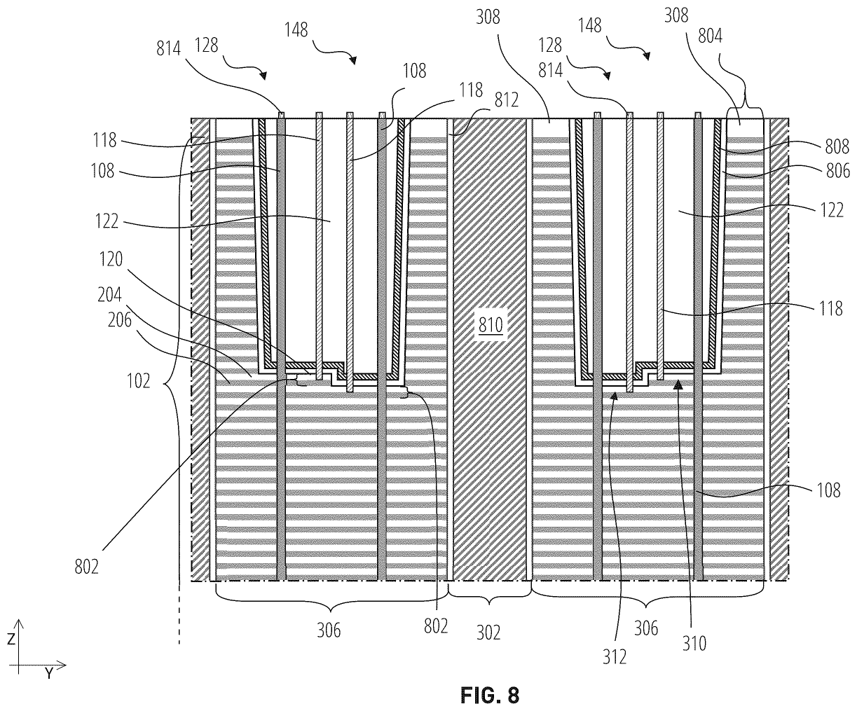

In some embodiments, the stadiums 128 (e.g., the shallow, multi-set stadiums 148 and the deep, single-set stadiums 150) are formed so that the staircase profiles of the stadium series of one block 306 (FIG. 3) substantially mirror that the staircase profiles of a longitudinally neighboring block 306. With reference to FIG. 8, illustrated are longitudinally neighboring blocks 306, with a view corresponding to line E-E of FIG. 6 and/or FIG. 7. FIG. 8 illustrates steps 120 of multi-set stadiums 148 of the blocks 306. The longitudinally neighboring blocks 306 may be mirrored about (e.g., across) the intervening slit structure 302. These longitudinally neighboring blocks 306 may be referred to herein as “mirrored blocks” 306. Accordingly, the steps 120 of the lower staircase set 312—of each one of the multi-set stadiums 148 of one pair of mirrored blocks 306—may be relatively proximate the slit structure 302 that is between the pair of neighboring blocks, and the steps 120 of the upper staircase set 310 of each of the multi-set stadium 148 of the pair may be relatively distal from the between-neighboring-blocks slit structure 302. Correspondingly, the next neighboring block 306 (e.g., a block 306 to the right of the blocks 306 illustrated in FIG. 8) may have a structure (and staircase profile) substantially mirroring that of the right-most illustrated block 306, such that the upper staircase set 310 is relatively proximate the intervening slit structure 302 and the lower staircase set 312 is relatively distal the slit structure 302. Thus, at any lateral (X-axis) position along the series of stadiums 128 of the mirrored blocks 306, the elevations of the steps 120 in the respective stadiums 128 may be substantially the same. However, the disclosure is not limited to this arrangement. In other embodiments, longitudinally neighboring blocks 306 are not mirrored.

FIG. 8 also illustrates, in more detail, the step contacts 118 extending to the conductive structures 206 of the steps 120, according to embodiments in which the step 120 treads are provided by areas of the insulative structures 204. In such embodiments, to reach the conductive structures 206 of the steps 120, each step contact 118 extends through the uppermost insulative structure 204 of the tier 202 that provides the steps 120 (e.g., stepped tier 802).

FIG. 8 also illustrates two bridges 308, one along the front and one along the rear of each block 306, according to the illustrated embodiment. The length (Y-axis dimension) of the bridge(s) 308 may be tailored to ensure a sufficient conductive rail 804 extends along the width (X-axis dimension) of the bridge 308 (and the width of the block 306), so that each of the conductive structures 206 of the stack 102 provides a substantially continuous conductive material region throughout the block 306.

As also shown in FIG. 8, one or more liners (e.g., first stadium liner 806, second stadium liner 808) and one or more non-conductive (e.g., insulative) material(s) forming the insulative fill region 122 may substantially fill the remaining openings (e.g., trenches)—referred to herein as “stadium openings” (e.g., “stadium trenches”)—vertically overlying and partially defined by the stadiums 128 (e.g., multi-set stadiums 148, single-set stadiums 150 (FIG. 1)). The liner(s) (e.g., first stadium liner 806, second stadium liner 808) and/or the insulative fill region 122 may electrically insulate the step contacts 118 and, for multi-set stadiums 148, the through-stack vias 108 from one another. The liners (e.g., first stadium liner 806, second stadium liner 808) and insulative fill region 122 are not illustrated in, e.g., FIGS. 3 through 7, and the liners are not illustrated in FIG. 1, solely for ease of viewing other features of the microelectronic device structures 100, 600, 700 in those figures.

Whether in shallow, multi-set stadiums 148 or in deep, single-set stadiums 150, each step contact 118 vertically extends through the insulative fill region 122, through the stadium liner(s) (e.g., the first stadium liner 806, the second stadium liner 808) and to or into the step 120 to make physical contact on or in the conductive structure 206 providing the step contact 118 landing of that step 120.

In some embodiments, the non-conductive material(s) of the insulative fill regions 122 are formed of and include one or more dielectric material(s) formed of and including any one or more insulative materials described above. The first stadium liner 806 and the second stadium liner 808 may each be formed of and include a different one or more of the insulative materials described above. In some embodiments, the first stadium liner 806 comprises, consists essentially of, or consists of an oxide (e.g., silicon dioxide), and the second stadium liner 808 comprises, consists essentially of, or consists of a nitride (e.g., silicon nitride).

Accordingly, disclosed is a microelectronic device comprising a stack structure comprising a vertically repeated sequence of tiers respectively comprising at least one insulative structure and at least one conductive structure. Slit structures extend through the stack structure to divide the stack structure into blocks. A series of stadiums are within the stack structure of one of the blocks and are horizontally spaced from one another by crests of the stack structure. The stadiums of the series are individually defined in unique groups of the tiers of the stack structure. The stadiums of the series individually comprise one or more staircases comprising steps. The series of stadiums comprises a first stadium and a second stadium. The first stadium is defined in a first tier group of the unique groups of the tiers. The second stadium is defined in a second tier group of the unique groups of the tiers. The first tier group is elevationally higher in the stack structure than the second tier group. Conductive step contacts extend to or into the steps. Conductive through-stack vias extend a height of the stack structure and are in electrical communication with the conductive step contacts. The conductive through-stack vias comprise some conductive through-stack vias that are within a horizontal area of the first stadium and that are in electrical communication with the conductive step contacts in the first stadium. The conductive through-stack vias also comprise other conductive through-stack vias that are within a horizontal area of the crests and that are in electrical communication with the conductive step contacts in the second stadium.

Also, in accordance with the embodiments disclosed herein, disclosed is a microelectronic device comprising a stack structure comprising a vertically repeated pattern of tiers, the tiers individually comprising insulative material and conductive material. Slit structures extend through the stack structure to define blocks of the stack structure. The blocks individually comprise a series of staircased stadiums. The series of staircased stadiums comprises at least one multi-set stadium comprising multiple sets of at least one staircase and comprises at least one single-set stadium comprising a single set of at least one staircase. Conductive step contacts extend to or into steps of the multiple sets of at least one staircase. Additional conductive step contacts extend to or into steps of the single set of at least one staircase. Conductive through-stack vias are within a horizontal area of the at least one multi-set stadium, extend a height of the stack structure, and are in electrical communication with the conductive step contacts. Additional conductive through-stack vias are outside a horizontal area of the at least one single-set stadium, extend the height of the stack structure, and are in electrical communication with the additional conductive step contacts.

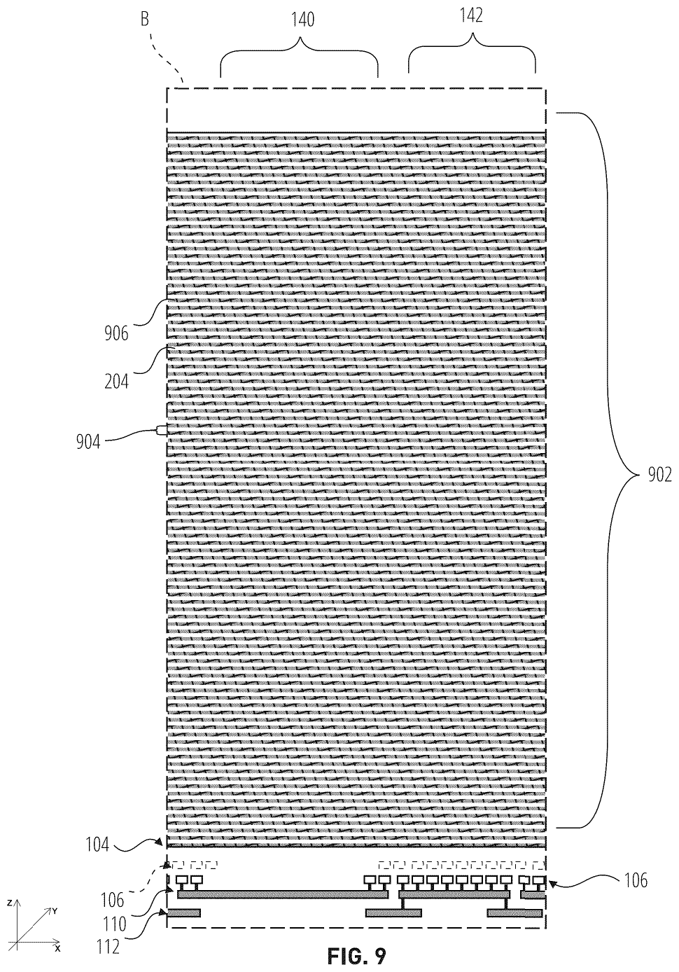

With reference to FIGS. 9 through 13, illustrated are various stages of forming a microelectronic device, such as one including the microelectronic device structure 100 of FIG. 1, the microelectronic device structure 600 of FIG. 6, and/or the microelectronic device structure 700 of FIG. 7.

With particular reference to FIG. 9, a precursor stack 902 (otherwise referred to herein as a “stack structure” or “tiered stack”) is formed on the base region 104, including in areas of the precursor stack 902—e.g., the first stadium area 130, the second stadium area 132, the third stadium area 134, the fourth stadium area 136, the fifth stadium area 138, the sixth stadium area 140, the seventh stadium area 142, and the eighth stadium area 144, described above—in which stadiums 128 (FIG. 1) will be formed.

In some embodiments, the precursor stack 902 has materials arranged in tiers 904 that are vertically repeated through at least a portion (e.g., a majority) of the precursor stack 902. The tiers 904 include the insulative structures 204 of the tiers 202 (FIG. 2) to be formed. In some embodiments, the tiers 904 also include sacrificial structures 906 where the conductive structures 206 (FIG. 2) are to be formed. These sacrificial structures 906 are eventually replaced with, or otherwise converted into, the conductive structures 206 (e.g., FIG. 2). In other embodiments, the precursor stack 902 are formed to include the conductive structures 206, instead of the sacrificial structures 906, even without replacement or conversion, such that the precursor stack 902 illustrated in FIG. 9 and other figures may represent the stack 102 of FIG. 1. Thus, in accordance with embodiments of the disclosure, the precursor stack 902 is formed to include the insulative structures 204 and “other structures,” which other structures may be either the sacrificial structures 906 or the final, conductive structures 206.

To form the precursor stack 902, formation (e.g., deposition) of the insulative structures 204 may be alternated with formation (e.g., deposition) of the other structures (e.g., the sacrificial structures 906). In some embodiments, the precursor stack 902 is formed, at this stage, to include as many tiers 904 with the sacrificial structures 906 as there will be tiers 202 (FIG. 2) with conductive structures 206 (FIG. 2) in the final stack 102 (FIG. 1) of the microelectronic device structure (e.g., the microelectronic device structure 100 (FIG. 1), the microelectronic device structure 600 (FIG. 6), and/or the microelectronic device structure 700 (FIG. 7)).

A relatively thicker upper insulative structure may be included atop the precursor stack 902 and may be formed of and include one or more insulative materials described above, such as the same insulative material(s) as the insulative structures 204 of the precursor stack 902. One or more masks (e.g., hardmasks) may also be included on (e.g., above) the precursor stack 902 (e.g., on the upper insulative structure) and utilized in subsequent material-removal (e.g., etching, patterning) processes.

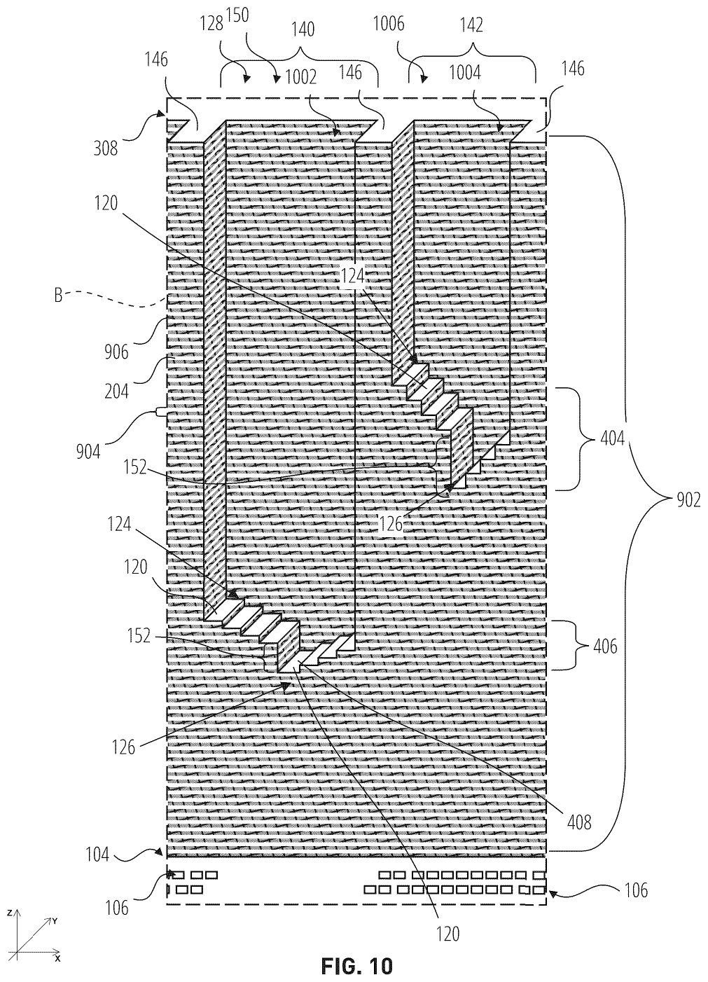

With reference to FIG. 10, the precursor stack 902 (and the upper insulative structure and/or mask, if present) may be patterned—in a series of material-removal (etching) and mask trimming stages—to form, in substantially the same (e.g., a common) uppermost group of tier 904 elevations, the staircase profiles of a single set of staircases for each stadium 128 (FIG. 1) to be formed. For the single-set stadiums 150 (FIG. 1), the initially-formed staircase profiles may be substantially the staircase profile of the final staircases (e.g., descending staircase 124 and ascending staircase 126 (FIG. 4)) to be formed. For the multi-set stadiums 148 (FIG. 1), the initially-formed staircase profiles may be substantially the staircase profile of the final upper staircase sets 310 (FIG. 4) to be formed.

Then, for at least stadiums 128 to occupy lower tier elevations, the initially-formed staircase profiles may be lowered, in one or more further material-removal (e.g., etching) stages, to extend each staircase profile to the elevation of its target tier group. Accordingly, with reference to FIG. 10, in the sixth stadium area 140, the profile of the descending staircase 124 and the ascending staircase 126 may be lowered to the elevation of the second tier group 406; and, in the seventh stadium area 142, the profile of the descending staircase 124 and the ascending staircase 126 of the upper staircase set 310 (FIG. 4) may be lowered to the elevation of the first tier group 404. Extending the staircase profiles forms stadium openings 1002 at the base of each of which is a completed single-set stadium 150, and forms intermediate stadium openings 1004 at the base of each of which is an intermediate stadium 1006 from which one of the multi-set stadiums 148 (FIG. 4) is to be formed. Areas of the precursor stack 902 for the crests 146 and the bridges 308 (FIG. 1) may not be etched such that these areas of the precursor stack 902 retain the full, initial height of the precursor stack 902.

As used herein, the term “stadium opening” (e.g., as in the stadium openings 1002 and the intermediate stadium openings 1004 of FIG. 10) means and includes an opening that has, along the width (X-axis dimension) of its base, the profiles of at least one set of staircases. Accordingly, the stadium openings 1002 and the intermediate stadium openings 1004 expose surfaces (e.g., step 120 treads) at different tier 904 elevations throughout the height of the staircases.

At this stage, the vertically highest of the staircases (e.g., the upper staircase set 310 (FIG. 4)) of the multi-set stadiums 148 may already be at their final elevations in the precursor stack 902.

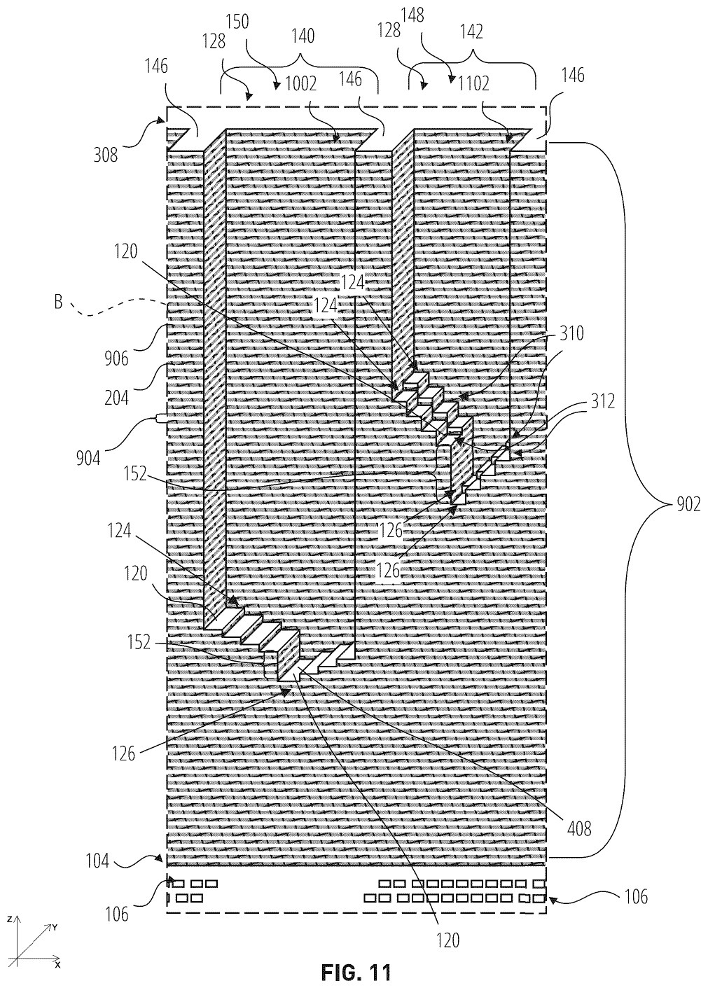

With reference to FIG. 11, the lower staircase set 312 of the multi-set stadiums 148 may be formed—concurrently or sequentially for the multi-set stadiums 148—by another material-removal (e.g., etching) process in the longitudinal half of the multi-set stadium 148 that includes the lower staircase set 312. For example, the staircase profile of the descending staircase 124 and the ascending staircase 126 of the lower staircase set 312 may be lowered by a height of one tier 904 in only one longitudinal half of each respective stadium area (e.g., the seventh stadium area 142) of a multi-set stadium 148, so as to form the lower staircase set 312 one tier 904 vertically below the upper staircase set 310. This may complete the final staircase profile for the multi-set stadiums 148 with a stadium opening 1102 above each multi-set stadium 148.

Though FIG. 11 illustrates performing the one-tier offset to form the lower staircase set 312 distinct from the upper staircase set 310 as a stage following extension of the earlier staircase profiles to a final tier group and depth, in other embodiments, the tier offset to distinguish the staircase sets of the multi-set stadiums 148 may be formed prior to extending the staircase profiles to final depths.

Once the single-set stadiums 150 and the multi-set stadiums 148 are at their final depths in the precursor stack 902, the liners (e.g., the first stadium liner 806, the second stadium liner 808 of FIG. 8) and the insulative fill region 122 (FIG. 8) may be sequentially formed (e.g., deposited, conformally deposited) in the stadium openings 1002 over the single-set stadiums 150 and in the stadium openings 1102 over the multi-set stadiums 148.

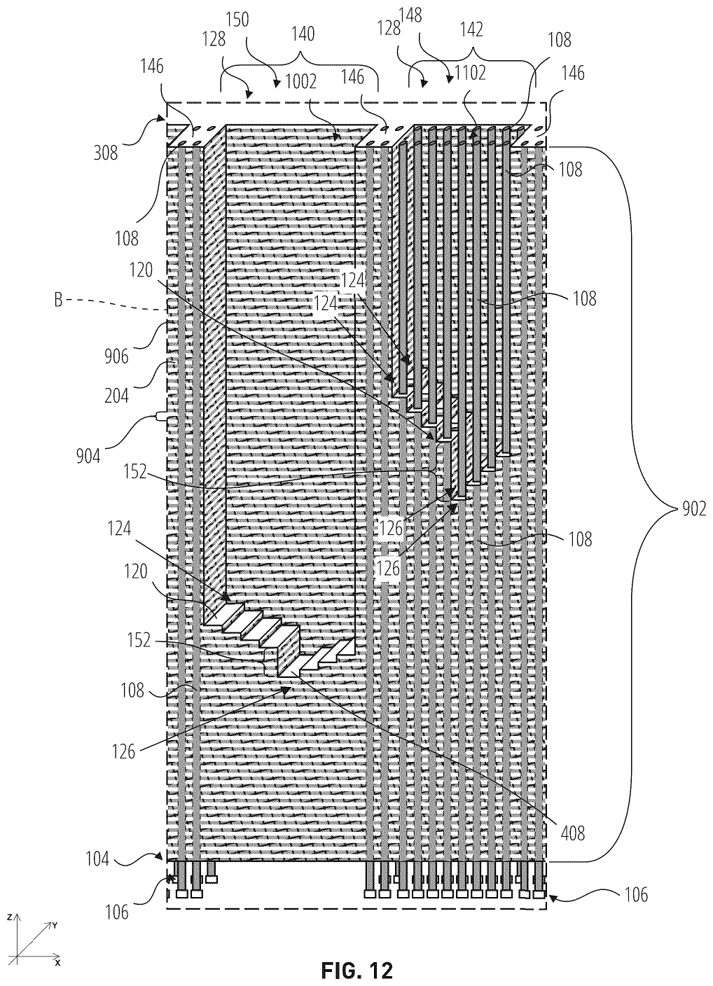

With reference to FIG. 12, the through-stack vias 108 may be formed, in their final horizontal arrangement, to extend to the conductive landings 106 below the precursor stack 902. The through-stack vias 108 (active) for the multi-set stadiums 148 may be formed to extend through the steps 120 of the multi-set stadiums 148. Some (e.g., most) or all of the through-stack vias 108 (active) for the single-set stadiums 150 may be formed to extend wholly through the materials of the precursor stack 902 in the crests 146. In some embodiments, such as for forming the microelectronic device structure 700 of FIG. 7, one or more of the through-stack vias 108 of the single-set stadiums 150 are formed in the landing areas 408 of the multi-set stadiums 148. In embodiments including support contacts 702 (e.g., FIG. 7), the support contacts 702 are also formed in their respective horizontal areas.

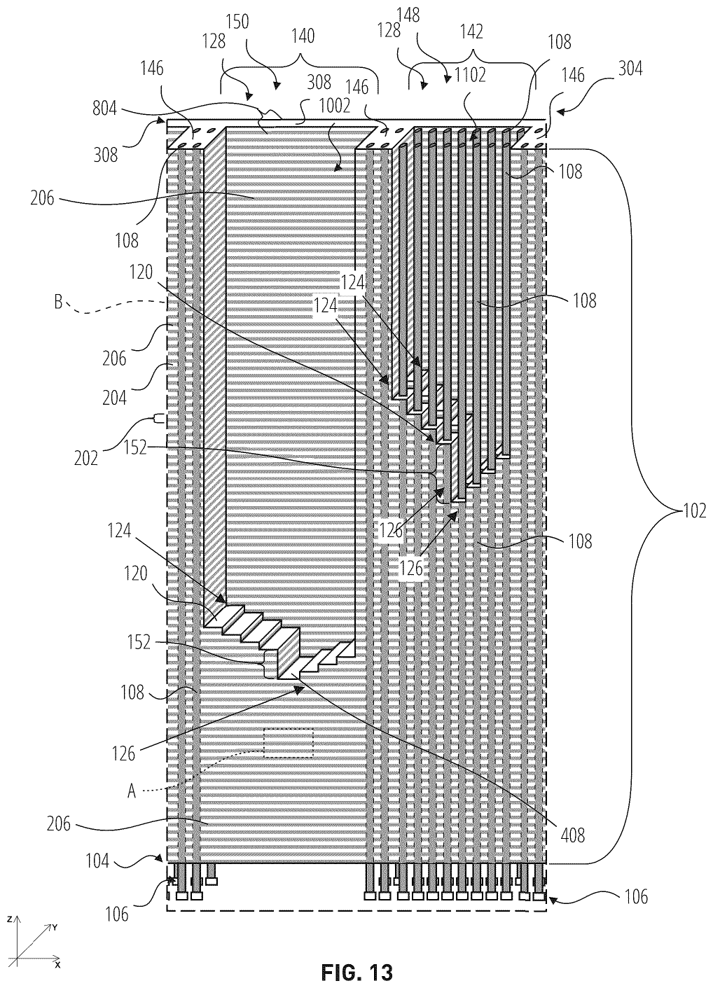

Though FIG. 13 illustrates the through-stack vias 108 all being formed after forming the stadium openings 1002, 1102 and the stadiums 128, in other embodiments, the through-stack vias 108 of the crest 146 areas may be formed prior to forming the stadium openings 1002, 1102 and the stadiums 128, and the remaining through-stack vias 108 may be formed in the horizontal area of the stadiums 128 after forming the stadium openings 1002, 1102 and the stadiums 128.

In some embodiments that include non-active through-stack vias (e.g., support contacts 702, such as in the microelectronic device structure 700 of FIG. 7), the support contacts 702 are formed concurrently with forming the through-stack vias 108, whether before or after forming the stadium openings 1002, 1102 and the stadiums 128.

In embodiments that include support contacts 702 in the crests 146 (such as in the microelectronic device structure 700 of FIG. 7), the support contacts 702 may be formed in the crests 146 prior to forming the stadium openings 1002, 1102 and the stadiums 128.

With reference to FIG. 13, the slits 304 may be formed (e.g., etched) through a whole height of the precursor stack 902 to divide the precursor stack 902 into the blocks 306 (FIG. 3). Forming the slits 304 also defines the bridges 308 along at least one of the rear side and the front side of individual blocks 306. During the material removal process to form the slits 304, the presence of the through-stack vias 108 and the support contacts 702, if any, may provide structural support to the materials of the blocks 306, which may inhibit or prevent leaning, bowing, or other structural defects of vertical walls being formed.

In embodiments in which the precursor stack 902 (FIG. 9) was formed to include sacrificial structures 906 (FIG. 9 and FIG. 12) that are not yet configured as the conductive structures 206, the sacrificial structures 906 may be substantially removed (e.g., exhumed)—by way of the slits 304—without substantially removing the insulative structures 204. The substantial removal of the sacrificial structures 906 forms voids between neighboring insulative structures 204. The insulative structures 204 may remain at substantially their initial elevations due to, e.g., support from the through-stack vias 108 and any support contacts 702 (FIG. 7) that may have already been formed in the fabrication process. For case of illustration, such optional support contacts 702 (FIG. 7) are not illustrated in FIG. 13. The presence of the through-stack vias 108 (and the support contacts 702, if any) may inhibit bending, sagging, and/or collapse of the insulative structures 204 and may also inhibit bowing, leaning, and other structural defects in the sidewalls 410 (FIG. 4) of the stadiums 128. This may also ensure that the bridges 308 (FIG. 8) may be accurately formed to provide for conductive rails 804 of at least a minimum dimension (Y-axis) to ensure each conductive structure 206 remains connected as a substantially continuous conductive region throughout the width and length of the block 306.

The conductive material(s) of the conductive structures 206 may then be formed (e.g., deposited, grown) in the voids between the insulative structures 204, via the slits 304, to complete the formation of the stack 102 with the repeated pattern of tiers 202 that include at least one of the insulative structures 204 and at least one of the conductive structures 206.

In other embodiments, the sacrificial structures 906 (FIG. 12) are not substantially removed and replaced, but are chemically converted to form the conductive material(s) of the conductive structures 206 to complete the formation of the stack 102.

With returned reference to FIG. 8, the slit structures 302 may be formed by forming (depositing) in the slits 304 (FIG. 13) non-conductive material(s), such as a non-conductive fill 810. In some embodiments, an insulative liner 812 is formed (e.g., conformally deposited) prior to forming the non-conductive fill 810. The insulative liner 812 may be formed of and include any of the aforementioned insulative material(s). The non-conductive fill 810 may be formed of and include any of the aforementioned insulative material(s) and/or semiconductor material(s).

With continued reference to FIG. 8 and with returned reference to FIG. 5, the step contacts 118 are formed to extend to or into the steps 120 to complete the microelectronic device structure 100 (FIG. 1), including the structure of FIG. 5.

With continued reference to FIG. 8, conductive regions 814 (FIG. 8) may be formed atop the active through-stack vias 108 (and may not be formed atop the non-electrically active through-stack vias (the support contacts 702)). Upper routing 116 (FIG. 1, FIG. 6, FIG. 7) may be formed to complete the electrical communication between the step contacts 118 and the through-stack vias 108, and thus also the string drivers 114 (FIG. 1).

Accordingly, disclosed is a method of forming a microelectronic device. The method comprises forming a stack structure comprising a vertically repeated sequence of tiers respectively comprising insulative material and sacrificial material. Stadium openings are formed in the stack structure. The stadium openings define a series of stadiums within the stack structure. The stadiums are spaced from one another by crest areas defined by non-patterned areas of the stack structure. The stadiums of the series are individually defined in unique groups of the tiers of the stack structure. The stadiums of the series individually comprise one or more staircases comprising steps. Forming the stadium openings comprises forming a first stadium opening and forming a second stadium opening. The first stadium opening defines a first stadium in a first tier group of the unique groups of the tiers. The second stadium opening defines a second stadium in a second tier group of the unique groups of the tiers. The first tier group is elevationally higher in the stack structure than the second tier group. Conductive step contacts are formed extending to or into the steps. Conductive through-stack vias are formed extending a height of the stack structure and in electrical communication with the conductive step contacts. Forming the through-stack vias comprises forming some of the conductive through-stack vias within a horizontal area of the first stadium and in electrical communication with the conductive step contacts in the first stadium. Forming the through-stack vias also comprises forming other of the conductive through-stack vias within a horizontal area of the second stadium and in electrical communication with the conductive step contacts in the second stadium.

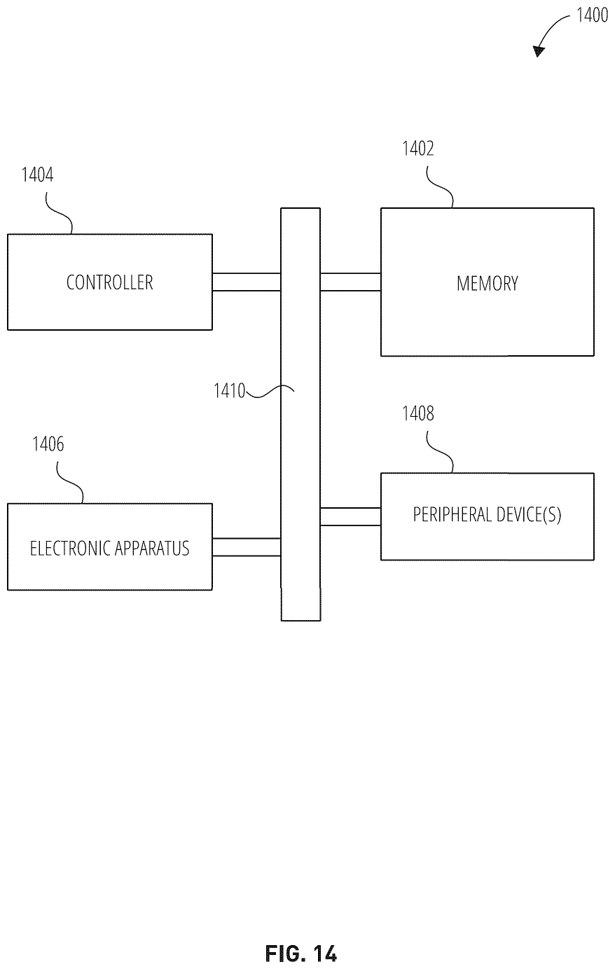

FIG. 14 shows a block diagram of a system 1400, according to embodiments of the disclosure, which system 1400 includes memory 1402 including arrays of vertical strings of memory cells adjacent microelectronic device structure(s) (e.g., the microelectronic device structure 100, 600, and/or 700 of FIG. 1, FIG. 6, and/or FIG. 7, respectively). Therefore, the architecture and structure of the memory 1402 may include one or more device structures according to embodiments of the disclosure and may be fabricated according to one or more of the methods described above (e.g., with reference to FIGS. 9 through 13).

The system 1400 may include a controller 1404 operatively coupled to the memory 1402. The system 1400 may also include another electronic apparatus 1406 and one or more peripheral device(s) 1408. The other electronic apparatus 1406 may include one or more of microelectronic device structures (e.g., the microelectronic device structure 100, 600, and/or 700 of FIG. 1, FIG. 6, and/or FIG. 7, respectively), according to embodiments of the disclosure and fabricated according to one or more of the methods described above. One or more of the controller 1404, the memory 1402, the other electronic apparatus 1406, and the peripheral device(s) 1408 may be in the form of one or more integrated circuits (ICs).

A bus 1410 provides electrical conductivity and operable communication between and/or among various components of the system 1400. The bus 1410 may include an address bus, a data bus, and a control bus, each independently configured. Alternatively, the bus 1410 may use conductive lines for providing one or more of address, data, or control, the use of which may be regulated by the controller 1404. The controller 1404 may be in the form of one or more processors.

The other electronic apparatus 1406 may include additional memory (e.g., with one or more microelectronic device structures (e.g., the microelectronic device structure 100, 600, and/or 700 of FIG. 1, FIG. 6, and/or FIG. 7, respectively), according to embodiments of the disclosure and fabricated according to one or more of the methods described above). Other memory structures of the memory 1402 and/or the other electronic apparatus 1406 may be configured in an architecture other than 3D NAND, such as dynamic random access memory (DRAM), static random access memory (SRAM), synchronous dynamic random access memory (SDRAM), synchronous graphics random access memory (SGRAM), double data rate dynamic ram (DDR), double data rate SDRAM, and/or magnetic-based memory (e.g., spin-transfer torque magnetic RAM (STT-MRAM)).

The peripheral device(s) 1408 may include displays, imaging devices, printing devices, wireless devices, additional storage memory, and/or control devices that may operate in conjunction with the controller 1404.

The system 1400 may include, for example, fiber optics systems or devices, electro-optic systems or devices, optical systems or devices, imaging systems or devices, and information handling systems or devices (e.g., wireless systems or devices, telecommunication systems or devices, and computers).

Accordingly, disclosed is an electronic system comprising at least one microelectronic device (e.g., including one or more of the microelectronic device structures 100 (FIG. 1), 600 (FIG. 6), 700 (FIG. 7), described above). The at least one microelectronic device is in electrical communication with at least one processor and/or with at least one peripheral device.

While the disclosed structures, apparatus (e.g., devices), systems, and methods are susceptible to various modifications and alternative forms in implementation thereof, specific embodiments have been shown by way of example in the drawings and have been described in detail herein. However, the disclosure is not intended to be limited to the particular forms disclosed. Rather, the disclosure encompasses all modifications, combinations, equivalents, variations, and alternatives falling within the scope of the disclosure as defined by the following appended claims and their legal equivalents.

What is claimed is:

1. A microelectronic device, comprising:
a stack structure comprising a vertically repeated sequence of tiers respectively comprising at least one insulative structure and at least one conductive structure;
slit structures extending through the stack structure to divide the stack structure into blocks;
a series of stadiums within the stack structure of one of the blocks and horizontally spaced from one another by crests of the stack structure, the stadiums of the series individually defined in unique groups of the tiers of the stack structure, the stadiums of the series individually comprising one or more staircases comprising steps, the series of stadiums comprising:
a first stadium defined in a first tier group of the unique groups of the tiers; and
a second stadium defined in a second tier group of the unique groups of the tiers, the first tier group being elevationally higher in the stack structure than the second tier group;
conductive step contacts extending to or into the steps; and
conductive through-stack vias extending a height of the stack structure and in electrical communication with the conductive step contacts, the conductive through-stack vias comprising:
some conductive through-stack vias within a horizontal area of the first stadium and in electrical communication with the conductive step contacts in the first stadium; and
other conductive through-stack vias within a horizontal area of the crests and in electrical communication with the conductive step contacts in the second stadium.

2. The microelectronic device of claim 1, further comprising at least one bridge area of the stack structure extending a width of the one of the blocks to provide a substantially continuous conductive region for each of the at least one conductive structure of the stack structure of the one of the blocks.

3. The microelectronic device of claim 2, wherein one of the bridges defines a rear of the one of the blocks and another of the bridges defines a front of the one of the blocks.

4. The microelectronic device of claim 1, wherein the first stadium comprises multiple sets of the one or more staircases.

5. The microelectronic device of claim 1, wherein the second stadium comprises a single set of the one or more staircases.

6. The microelectronic device of claim 1, wherein the one or more staircases of individual of the stadiums of the series are arranged in at least one set, each set of the at least one set comprising a descending staircase and an ascending staircase.

7. The microelectronic device of claim 6, wherein the descending staircase is vertically offset from the ascending staircase.

8. The microelectronic device of claim 6, wherein, within the first stadium, a riser height between neighboring steps of the steps of the descending staircase and between neighboring steps of the steps of the ascending staircase is a height of multiple of the tiers.

9. The microelectronic device of claim 8, wherein, within the second stadium, a riser height between neighboring steps of the steps of the descending staircase and between neighboring steps of the steps of the ascending staircase is a height of a single one of the tiers.

10. A microelectronic device, comprising:
a stack structure comprising a vertically repeated pattern of tiers, the tiers individually comprising insulative material and conductive material;
slit structures extending through the stack structure to define blocks of the stack structure;
the blocks individually comprising a series of staircased stadiums comprising:
at least one multi-set stadium comprising multiple sets of at least one staircase; and
at least one single-set stadium comprising a single set of at least one staircase;
conductive step contacts extending to or into steps of the multiple sets of at least one staircase;
additional conductive step contacts extending to or into steps of the single set of at least one staircase;
conductive through-stack vias within a horizontal area of the at least one multi-set stadium, extending a height of the stack structure, and in electrical communication with the conductive step contacts; and
additional conductive through-stack vias outside a horizontal area of the at least one single-set stadium, extending the height of the stack structure, and in electrical communication with the additional conductive step contacts.

11. The microelectronic device of claim 10, wherein the at least one multi-set stadium is defined in a group of the tiers that is elevationally higher in the stack structure than another group of the tiers in which the at least one single-set stadium is defined.

12. The microelectronic device of claim 10, wherein:
the conductive through-stack vias extend in part through the stack structure; and
the additional conductive through-stack vias extend substantially in their entirety through the stack structure.

13. The microelectronic device of claim 10, further comprising other conductive through-stack vias inside a horizontal area of a lowest of the steps of the at least one single-set stadium, extending the height of the stack structure, and in electrical communication with other conductive step contacts extending to or into other steps of the single set of at least one staircase.

14. The microelectronic device of claim 10, wherein the conductive through-stack vias and the additional conductive through-stack vias extend to conductive landing regions in a base region below the stack structure.

15. The microelectronic device of claim 14, wherein the base region further comprises multiple elevations of conductive routing to provide electrical communication between the conductive landing regions and string drivers.

16. The microelectronic device of claim 10, further comprising support contact structures extending the height of the stack structure, the support contact structures electrically isolated from all of the conductive step contacts.

17. The microelectronic device of claim 10, wherein:
the conductive step contacts extending to or into the steps of the multiple sets of the at least one staircase are each in electrical communication with one of the conductive through-stack vias that is within the horizontal area of the at least one multi-set stadium; and
the additional conductive step contacts extending to or into the steps of the single set of the at least one staircase are each in electrical communication with one of the additional conductive through-stack vias that are outside the horizontal area of the at least one single-set stadium.

18. A method of forming a microelectronic device, comprising:
forming a stack structure comprising a vertically repeated sequence of tiers respectively comprising insulative material and sacrificial material;
forming stadium openings in the stack structure, the stadium openings defining a series of stadiums within the stack structure, the stadiums spaced from one another by crest areas defined by non-patterned areas of the stack structure, the stadiums of the series individually defined in unique groups of the tiers of the stack structure, the stadiums of the series individually comprising one or more staircases comprising steps, forming the stadium openings comprising:
forming a first stadium opening defining a first stadium in a first tier group of the unique groups of the tiers; and
forming a second stadium opening defining a second stadium in a second tier group of the unique groups of the tiers, the first tier group being elevationally higher in the stack structure than the second tier group;
forming conductive step contacts extending to or into the steps; and
forming conductive through-stack vias extending a height of the stack structure and in electrical communication with the conductive step contacts, comprising:
forming some of the conductive through-stack vias within a horizontal area of the first stadium and in electrical communication with the conductive step contacts in the first stadium; and
forming other of the conductive through-stack vias within a horizontal area of the second stadium and in electrical communication with the conductive step contacts in the second stadium.

19. The method of claim 18, wherein forming the some of the conductive through-stack vias within the horizontal area of the first stadium comprises forming the some of the conductive through-stack vias to extend through the steps of the first stadium.

20. The method of claim 18, further comprising, after forming the conductive through-stack vias, substantially replacing or converting the sacrificial material of the stack structure with conductive material.
